(19) United States
(12) Patent Application Publication
(10) Pub. No.: US 2025/0089309 A1
(43) Pub. Date: Mar. 13, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventor: Tzu-Ging LIN, Kaohsiung (TW)

(21) Appl. No.: 18/403,776

(22) Filed: Jan. 4, 2024

Related U.S. Application Data
(60) Provisional application No. 63/538,072, filed on Sep. 13, 2023.

(51) Int. Cl. H01L 29/06; H01L 29/423; H01L 29/66; H01L 29/775

(52) U.S. Cl. CPC H10D 62/115; H10D 30/014; H10D 30/43; H10D 30/6735; H10D 64/017

(57) ABSTRACT

A semiconductor device structure, along with methods of forming such, are described. The semiconductor device structure includes a substrate, a source/drain feature disposed over the substrate, a gate spacer disposed over the source/drain feature, and a first isolation trench structure disposed over the substrate. The first isolation trench includes an upper portion adjacent to the gate spacer, a middle portion disposed below the upper portion and adjacent to a first side of the source/drain feature, and a lower portion disposed below the middle portion and extending into the substrate, wherein the lower portion has a bowing profile extending outwardly from one side of the first isolation trench structure.

### CROSS-REFERENCE TO RELATED APPLICATIONS

This application claims priority to U.S. Provisional Application Ser. No. 63/538,072 filed Sep. 13, 2023, which is incorporated by reference in their entirety.

### BACKGROUND

As the semiconductor industry has progressed into nanometer technology process nodes in pursuit of higher device density, higher performance, and lower costs, challenges from both fabrication and design issues have resulted in the development of multi-gate devices, such as fin field-effect transistors (FinFETs) and gate-all-around (GAA) transistors. To continue to provide the desired scaling and increased density for multi-gate devices in advanced technology nodes, continued reduction of the gate pitch is necessary. Various schemes, such as poly on diffusion edge (PODE) and continuous poly on diffusion edge (CPODE), have been used to scale the gate pitch while preventing leakage current between transistors. However, such schemes cannot provide the level of device density, cell isolation, and device performance required for aggressively scaled circuits and devices.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure in accordance with some embodiments.

FIGS. 7A-11A are cross-sectional side views of various stages of manufacturing the semiconductor device structure taken along cross-section A-A of FIG. 6, in accordance with some embodiments.

FIGS. 7B-11B are cross-sectional side views of various stages of manufacturing the semiconductor device structure taken along cross-section B-B of FIG. 6, in accordance with some embodiments.

FIGS. 7C-11C are cross-sectional side views of various stages of manufacturing the semiconductor device structure taken along cross-section C-C of FIG. 6, in accordance with some embodiments.

FIGS. 12A-12B to 18A-18B, 21A-21B, 25A-25B to 27A-27B are cross-sectional side views of one of various stages of manufacturing the semiconductor device structure of FIGS. 11A and 11B showing multiple fin structures disposed along the X and Y directions, respectively, in accordance with some embodiments.

FIG. 16A-1 illustrates an enlarged view of a portion of the semiconductor device structure of FIG. 16A.

FIG. 20-1 is a cross-sectional view of a portion of fin structures selected for a long isolation trench in a semi-isolated pattern region taken along cross-section D-D of FIG. 20-3, in accordance with some embodiments.

FIG. 20-2 is a cross-sectional view of a portion of fin structures selected for a short isolation trench in the semi-isolated pattern region taken along cross-section E-E of FIG. 20-3, in accordance with some embodiments.

FIG. 20-3 is a top view of a portion of the semi-isolated pattern region having the long isolation trench and the short isolation trench, in accordance with some embodiments.

FIG. 22-1 is a schematic top view of a portion of a patterned photoresist top layer, in accordance with some embodiments.

FIG. 22-2 is a schematic top view of a portion of the long isolation trench structures using the patterned photoresist top layer of FIG. 22-1 as an etching mask.

FIG. 22-3 is a schematic top view of a semi-isolated pattern region having a dense pattern region disposed between a first isolation region and a second isolation region 2228.

FIG. 23-1 is a schematic top view of a portion of a patterned photoresist top layer having openings for forming a long isolation trench structure and a short isolation trench structure of FIG. 23-3, in accordance with some embodiments.

FIG. 23-2 is a schematic top view of a portion of long and short isolation trench structures formed using the patterned photoresist top layer of FIG. 23-1 as an etching mask. FIG. 23-3 is a schematic top view of a semi-isolated pattern region, in accordance with some embodiments.

FIGS. 23-4 is a cross-sectional view of a portion of the semiconductor device structure showing the long and short isolation trench structures in the semi-isolated pattern region taken along cross-section F-F of FIG. 23-3, in accordance with some embodiments.

FIGS. 23-5 is a cross-sectional view of a portion of the semiconductor device structure showing the short isolation trench structures in the semi-isolated pattern region taken along cross-section F-F of FIG. 23-3, in accordance with some embodiments.

FIG. 24-1 is a schematic top view of a portion of a patterned photoresist top layer having openings for forming a short isolation trench structure and a long isolation trench structure of FIG. 24-3, in accordance with some embodiments.

FIG. 24-2 is a schematic top view of a portion of short and long isolation trench structures formed using the patterned photoresist top layer of FIG. 24-1 as an etching mask.

FIG. 24-3 is a schematic top view of a semi-isolated pattern region, in accordance with some embodiments.

FIG. 28 illustrates a cross-sectional view of a portion of the semiconductor device structure showing the isolation trench structure, in accordance with some embodiments.

FIG. 29 illustrates a cross-sectional view of a portion of the semiconductor device structure showing the isolation trench structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Presented herein are embodiments of semiconductor device structures and methods for fabricating such device structures. Methods described herein may be easily integrated into the current process flow. Further, methods described herein relate to the formation of an insulation structure, such as a Continuous-Poly-On-Diffusion-Edge (CPODE) structure, that removes a portion of, or a selected fin structure in its entirety, and replaced with it with an insulating material to form isolation regions. The CPODE structures avoid leakage current through epitaxial source/drain features, transistors, and silicon substrates. While the embodiments of the present disclosure describe a CPODE-first processing methods, i.e., during front-end-of-line (FEOL) processing before metal gate formation, the embodiments are equally applicable to a CPODE-last processing method (or so-called CMODE process), i.e., during middle-end-of-line (MEOL) processing after metal gate formation is formed.

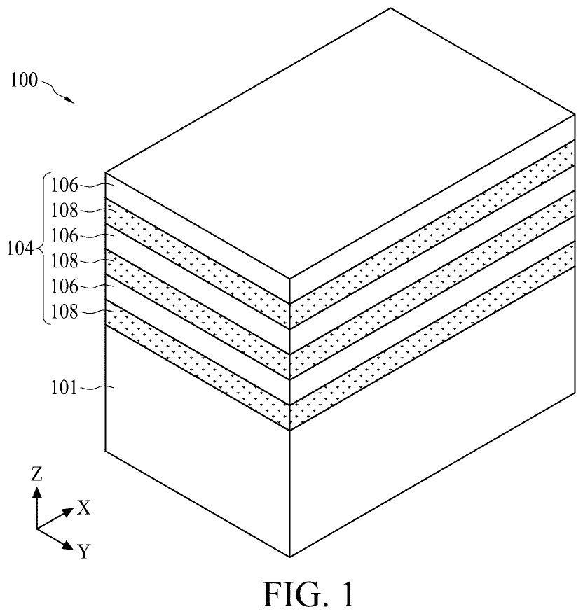

FIGS. 1 to 28 show exemplary processes for manufacturing a semiconductor device structure 100 according to embodiments of the present disclosure. It is understood that additional operations can be provided before, during, and after processes shown by FIGS. 1 to 28, and some of the operations described below can be replaced or eliminated, for additional embodiments of the method. The order of the operations/processes is not limiting and may be interchangeable.

The substrate 101 may include various regions that have been doped with impurities (e.g., dopants having p-type or n-type impurities). Depending on circuit design, the dopants may be, for example boron for p-type field effect transistors (p-type FETs) and phosphorus for n-type field effect transistors (n-type FETs).

The stack of semiconductor layers 104 includes alternating semiconductor layers made of different materials to facilitate formation of nanosheet channels in a multi-gate device, such as nanosheet channel FETs. In some embodiments, the stack of semiconductor layers 104 includes first semiconductor layers 106 and second semiconductor layers 108 vertically stacked over the substrate 101. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GalnP, GalnAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

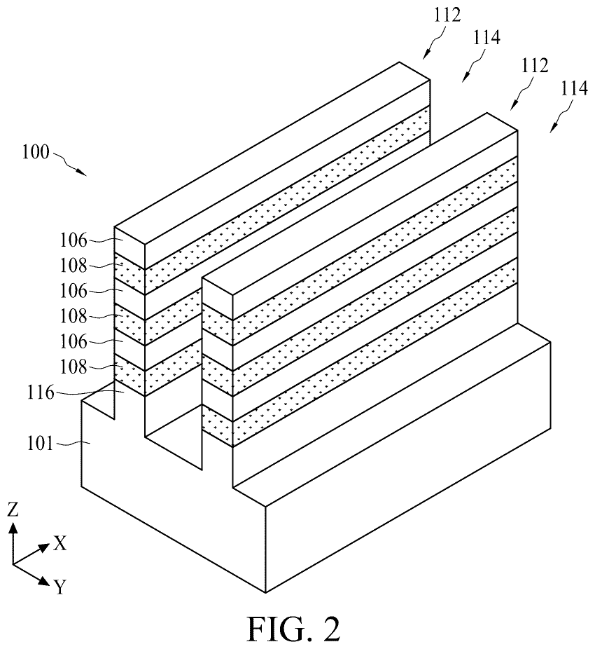

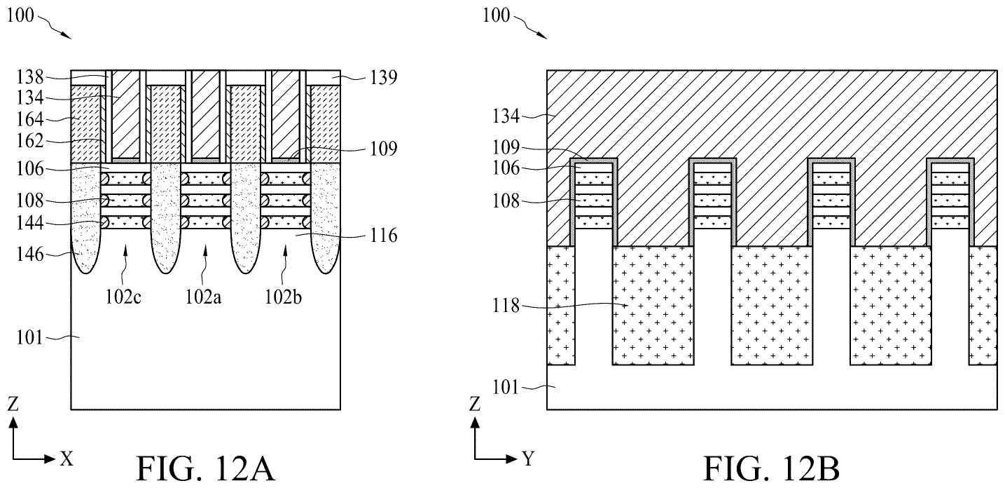

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof. As shown in FIG. 2, two fins are formed, but the number of the fins is not limited to two. Three or more fins are arranged along the X direction in some embodiments, as shown in FIGS. 12A-12B to 28A-28B.

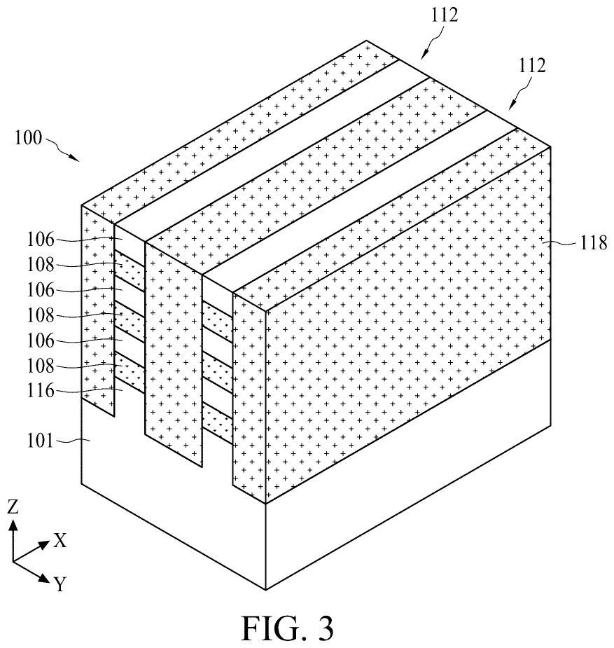

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

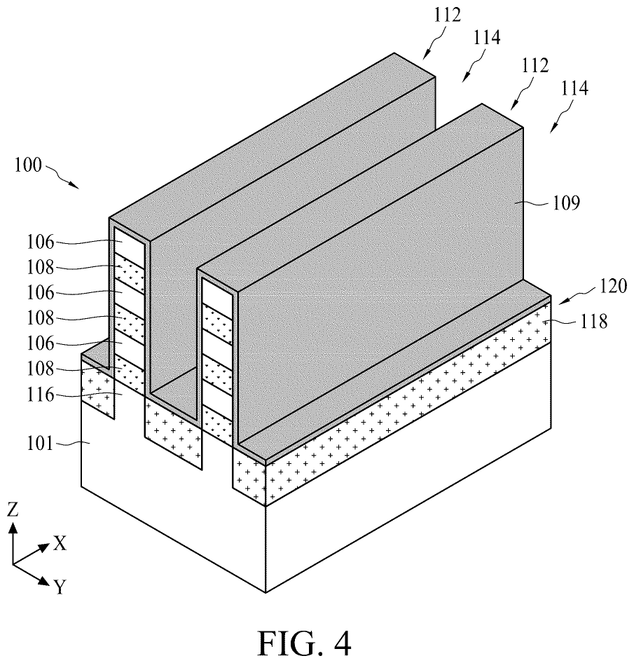

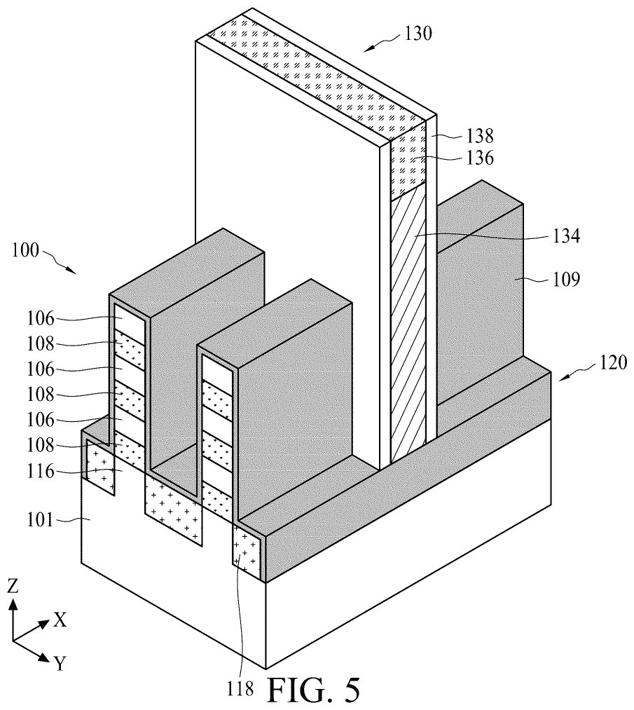

In FIG. 4, the insulating material 118 is recessed to form an isolation region 120. The recess of the insulating material 118 exposes portions of the fin structures 112, such as the stack of semiconductor layers 104. The recess of the insulating material 118 reveals the trenches 114 between the neighboring fin structures 112. The isolation region 120 may be formed using a suitable process, such as a dry etching process, a wet etching process, or a combination thereof. A top surface of the insulating material 118 may be level with or at a below a surface of the second semiconductor layers 108 in contact with the well portion 116 formed from the substrate 101. Thereafter, an optional liner 109 is formed on the isolation region 120 and exposed surfaces of the fin structures 112. The liner 109 may be made of an oxygen-containing material, a dielectric material, such as SiO₂, SiN, SiCN, SiOC, SiOCN, or the like, or any suitable material that has high etch selectivity with respect to the first and second semiconductor layers 106, 108. The liner 109 may be formed by a conformal process, such as an ALD process. The liner 109 may have a thickness ranging from about 1 nm to about 6 nm. The liner 19 protects the first and second semiconductor layers 106, 108 from being damaged during the subsequent removal of the sacrificial gate structure. The liner 109 may also serve as a sacrificial gate dielectric layer for the subsequent sacrificial gate structures 130 (FIG. 5). The liner 109 may be a conformal layer and may be formed by a conformal process, such as an atomic layer deposition (ALD) process. The term “conformal” may be used herein for ease of description upon a layer having substantial same thickness over various regions.

In FIG. 4, an insulating material 402 is formed on the substrate 101. The insulating material 402 fills the trench 204 (FIG. 3). The insulating material 402 may be first formed over the substrate 101 so that the fins 202a, 202b are embedded in the insulating material 402. Then, a planarization operation, such as a chemical mechanical polishing (CMP) process and/or an etch-back process, is performed such that the tops of the fins 202a, 202b (e.g., the liner 304) are exposed from the insulating material 402, as shown in FIG. 4. The insulating material 402 may be made of an oxygen-containing material, such as silicon oxide or fluorine-doped silicate glass (FSG); a nitrogen-containing material, such as silicon nitride, silicon oxynitride (SiON), SiOCN, SiCN; a low-K dielectric material; or any suitable dielectric material. The insulating material 402 may be formed by any suitable method, such as low-pressure chemical vapor deposition (LPCVD), plasma enhanced CVD (PECVD) or flowable CVD (FCVD).

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate electrode layer 134 and a mask layer 136. The liner 109 may serve as a sacrificial gate dielectric layer. The sacrificial gate electrode layer 134 and the mask layer 136 may be formed by sequentially depositing blanket layers of the sacrificial gate electrode layer 134 and the mask layer 136, and then patterning these layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. While one sacrificial gate structure 130 is shown, it should be understood that two or more sacrificial gate structures 130 may be arranged along the X direction, such as the embodiments shown in FIGS. 12A-12B to 28A-28B.

The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 serve as channel regions for the semiconductor device structure 100. The fin structures 112 that are partially exposed on opposite sides of the sacrificial gate structure 130 define source/drain (S/D) regions for the semiconductor device structure 100. In some cases, some S/D regions may be shared between various transistors. For example, various one of the S/D regions may be connected together and implemented as multiple functional transistors.

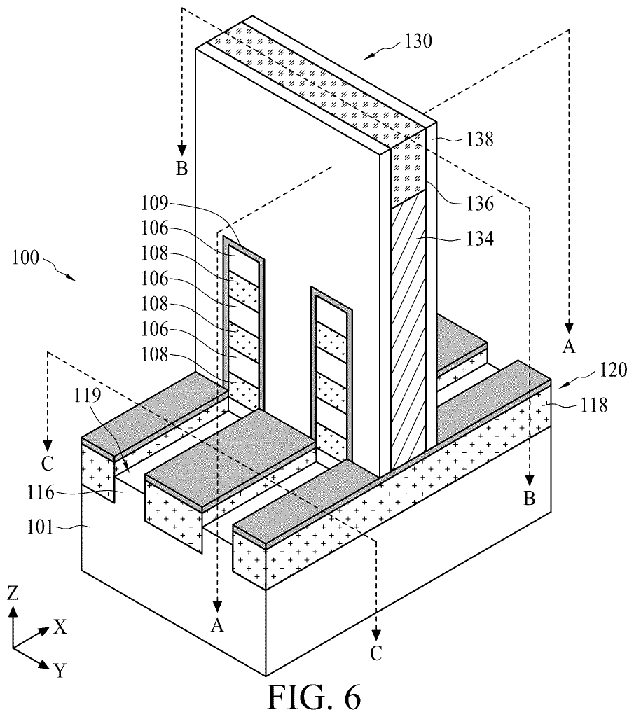

In FIG. 6, the portions of the fin structures 112 in the S/D regions (e.g., regions on opposite sides of the sacrificial gate structure 130) are recessed down below the top surface of the isolation region 120 (or the insulating material 118), by removing portions of the fin structures 112 not covered by the sacrificial gate structure 130. The recess of the portions of the fin structures 112 can be done by an etch process, either isotropic or anisotropic etch process, or further, may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. Trenches 119 are formed in the S/D regions as the result of the recess of the portions of the fin structures 112.

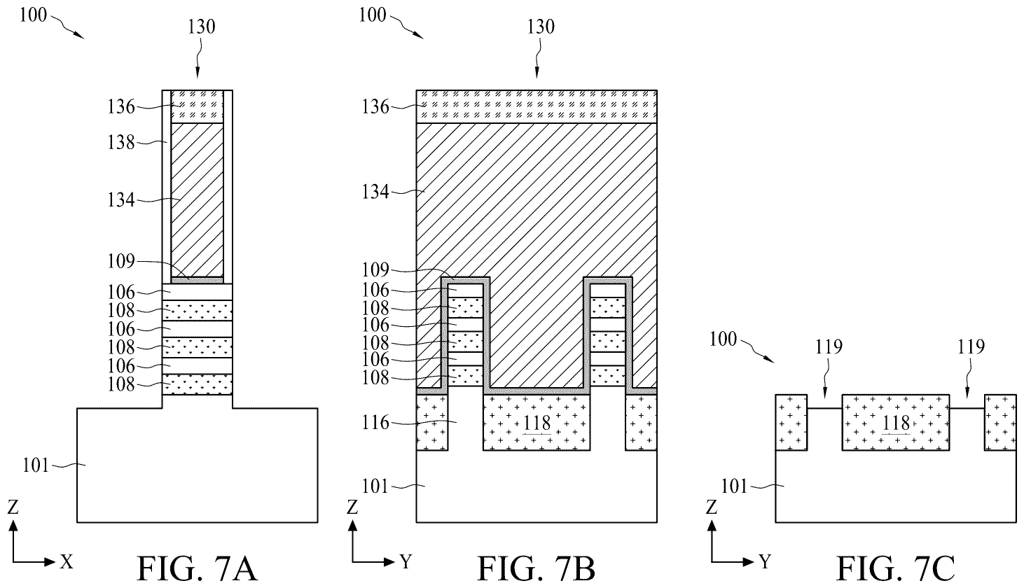

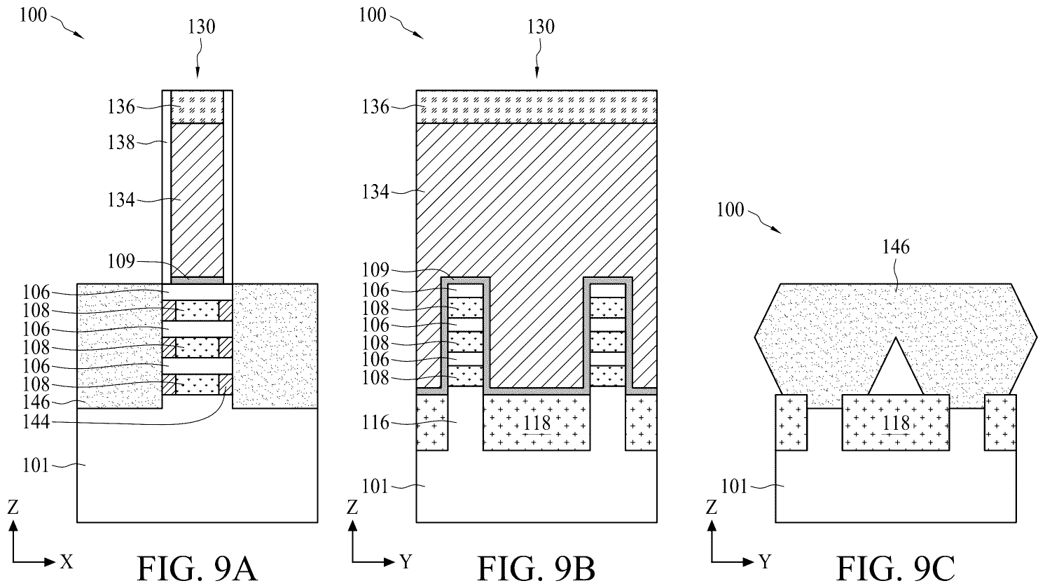

FIGS. 7A-11A are cross-sectional side views of various stages of manufacturing the semiconductor device structure 100 taken along cross-section A-A of FIG. 6, in accordance with some embodiments. FIGS. 7B-11B are cross-sectional side views of various stages of manufacturing the semiconductor device structure 100 taken along cross-section B-B of FIG. 6, in accordance with some embodiments. FIGS. 7C-11C are cross-sectional side views of various stages of manufacturing the semiconductor device structure 100 taken along cross-section C-C of FIG. 6, in accordance with some embodiments. Cross-section A-A are in a plane of the fin structure 112 (FIG. 4) along the X direction. Cross-section B-B is in a plane perpendicular to cross-section A-A and is in the sacrificial gate structure 130 along the Y direction. Cross-section C-C is in a plane perpendicular to cross-section A-A and is in the S/D features 146 (FIG. 9A) along the Y-direction.

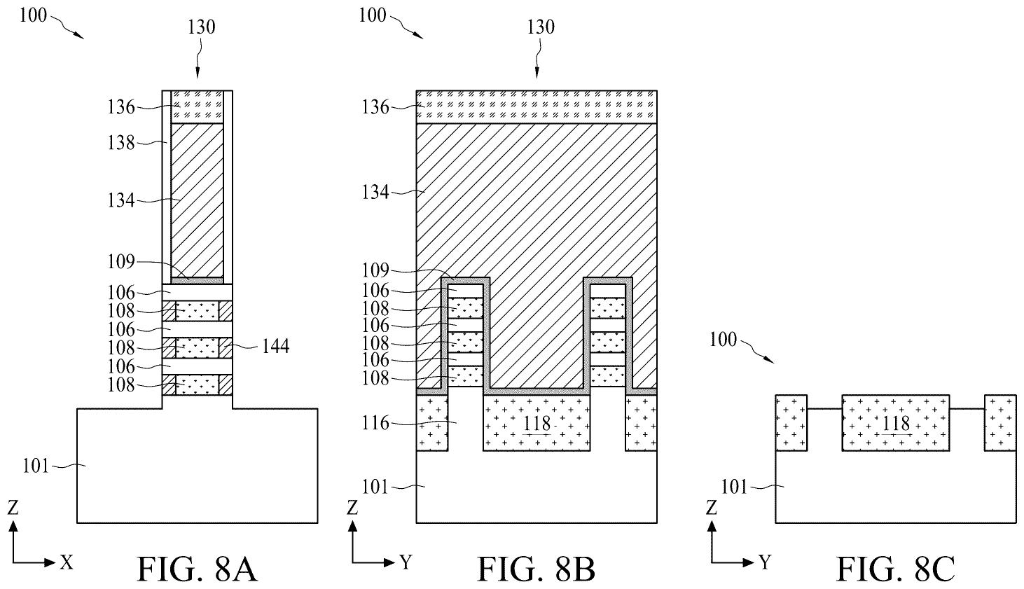

In FIGS. 8A-8C, edge portions of each second semiconductor layer 108 of the stack of semiconductor layers 104 are removed horizontally along the X direction. The removal of the edge portions of the second semiconductor layers 108 forms cavities. In some embodiments, the edge portions of the second semiconductor layers 108 are removed by a selective wet etching process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

Next, a dielectric layer is formed on exposed surfaces of the sacrificial gate structures 130 and the first and second semiconductor layers 106, 108. The dielectric layer also fills in the cavities provided by removal of the edge portions of the second semiconductor layers 108. Suitable materials for the dielectric layer may include, but are not limited to, SiO₂, Si₃N₄, SiC, SiCP, SION, SiOC, SiCN, SiOCN, and/or other suitable material. Other materials, such as low-k materials with a k value less than about 3.5, may also be used. The dielectric layer may be formed by a conformal deposition process, such as ALD. Then, a removal process, such as an anisotropic etching process, is performed so that only portions of the dielectric layer 144 remain in the cavities to form inner spacers 144. The remaining second semiconductor layers 108 are capped between the inner spacers 144 along the X direction.

In FIGS. 9A-9C, epitaxial S/D features 146 are formed in the source/drain (S/D) regions. The epitaxial S/D features 146 may grow laterally from the first semiconductor layers 106. The epitaxial S/D feature 146 may include one or more layers of Si, SiP, SiC and SiCP for an n-type FET or Si, SiGe, Ge for a p-type FET. The epitaxial S/D features 146 may be formed by an epitaxial growth method using selective epitaxial growth (SEG), CVD, ALD or MBE. The epitaxial S/D features 146 are in contact with the first semiconductor layers 106 and the inner spacers 144. The second semiconductor layer 108 under the sacrificial gate structure 130 are separated from the epitaxial S/D features 146 by the dielectric spacers 144. The epitaxial S/D features 146 may grow both vertically and horizontally to form facets, which may correspond to crystalline planes of the material used for the first semiconductor layers 106. In some cases, the epitaxial S/D features 146 of a fin structure may grow and merge with the epitaxial S/D features 146 of the neighboring fin structures, as one example shown in FIG. 9C.

The epitaxial S/D features 146 may be the S/D regions. For example, one of a pair of epitaxial S/D features 146 located on one side of the sacrificial gate structures 130 may be a source region, and the other of the pair of epitaxial S/D features 146 located on the other side of the sacrificial gate structures 130 may be a drain region. A pair of S/D epitaxial features 146 includes a source epitaxial feature 146 and a drain epitaxial feature 146 connected by the channels (i.e., the first semiconductor layers 106). Source/drain region(s) may refer to a source or a drain, individually or collectively dependent upon the context. In this disclosure, a source and a drain are interchangeably used, and the structures thereof are substantially the same.

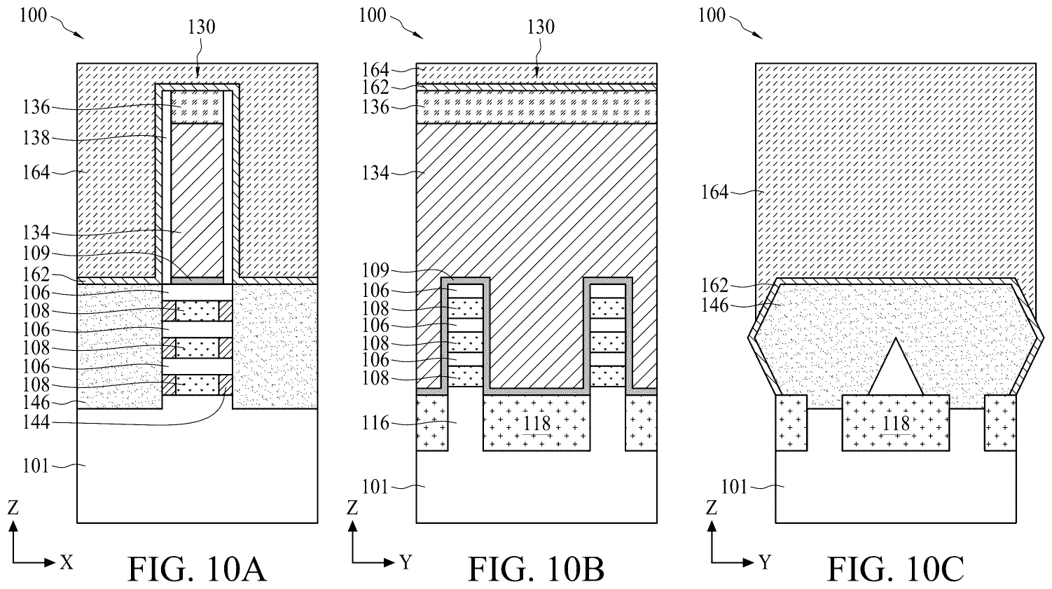

In FIGS. 10A-10C, a contact etch stop layer (CESL) 162 is conformally formed on the exposed surfaces of the semiconductor device structure 100. The CESL 162 covers the top surfaces of the sacrificial gate structure 130, the insulating material 118, the epitaxial S/D features 146, and the exposed surface of the stack of semiconductor layers 104. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds comprising Si, O, C, and/or H, such as silicon oxide, TEOS oxide, SiCOH and SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

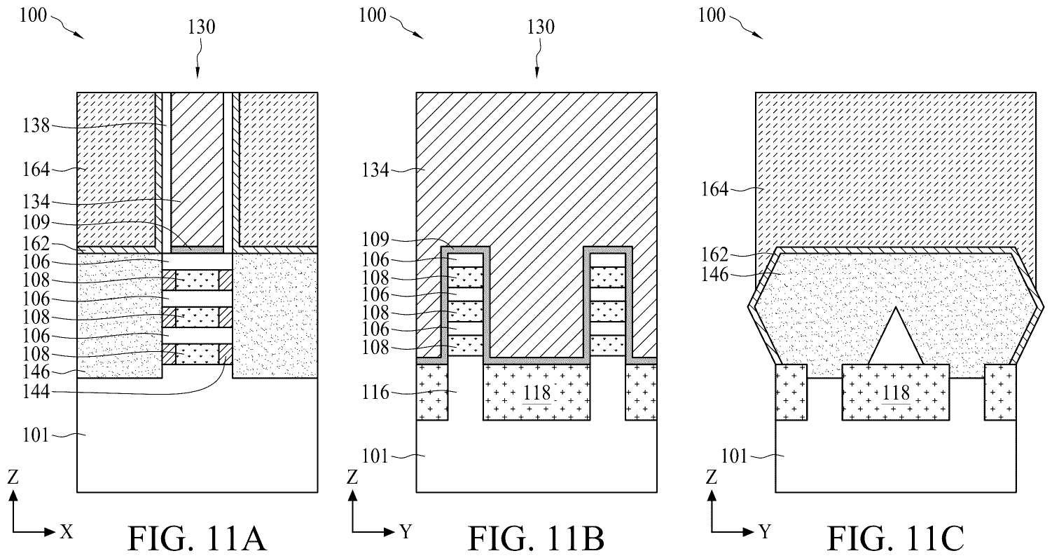

In FIGS. 11A-11C, after the ILD layer 164 is formed, a planarization operation, such as CMP, is performed on the semiconductor device structure 100 until the sacrificial gate electrode layer 134 is exposed. The top surfaces of the sacrificial gate electrode layer 134, the gate spacers 138, the CESL 162, and the ILD layer 164 are substantially co-planar after the CMP.

FIGS. 12A-12B to 18A-18B, 21A-21B, 25A-25B to 28A-28B are cross-sectional side views of one of various stages of manufacturing the semiconductor device structure 100 of FIGS. 11A and 11B showing multiple fin structures disposed along the X and Y directions, respectively, in accordance with some embodiments. FIGS. 12A and 12B show an embodiment where the ILD layer 164 is recessed to a level below the top of the sacrificial gate electrode layer 134 prior to the CMP process. In such cases, a cap layer 139, such as a SiN, SiCN, or TiN layer, may be formed on the recessed ILD layer 164. The cap layer 139 may protect the ILD layer 164 during subsequent CMP and etch processes. After the planarization process, the top surfaces of the cap layer 139, the CESL 162, the gate spacers 138, and the sacrificial gate electrode layer 134 are substantially co-planar. Although three fin structures are illustrated in the Y-cut figures, it is understood that depending on the desired design and number of the GAA semiconductor device structure 100, any suitable number of fin structures may be formed in the multi-layer structure to form the desired GAA semiconductor device structures 100.

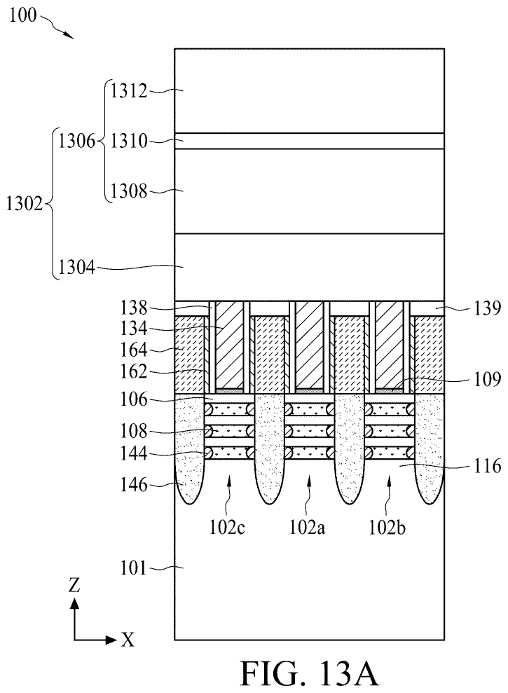

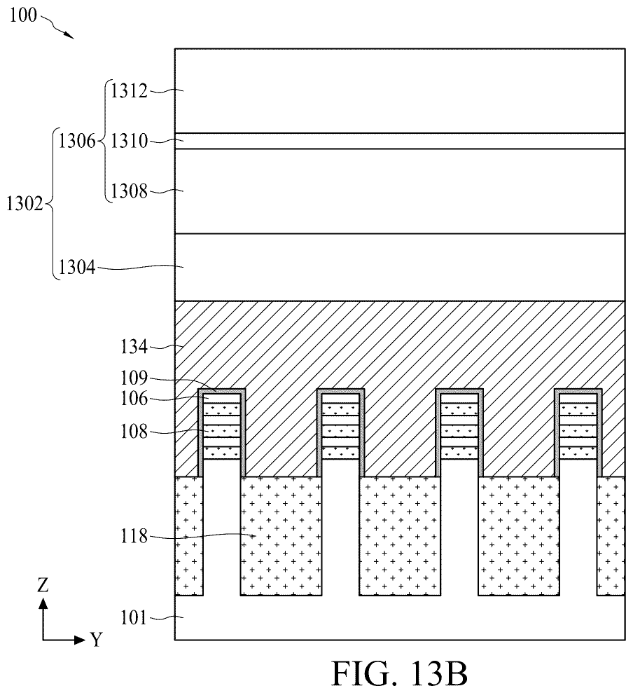

In FIGS. 13A and 13B, a mask structure 1302 is formed on the top surfaces of the sacrificial gate electrode layer 134, the gate spacers 138, the CESL 162, and the cap layer 139 (or the ILD layer 164 if the cap layer 139 were not formed). The mask structure 1302 may include a hard mask 1304 and a resist layer 1306. The hard mask 1304 may be any suitable masking material. In some embodiments, the hard mask 1304 is formed of a nitrogen-containing material, such as a SiN or SiCN. The resist layer 1306 may be a single layer photoresist or a tri-layer photoresist. An exemplary tri-layer photoresist may include a bottom layer 1308, a middle layer 1310 disposed over the bottom layer 1308, and a photoresist top layer 1312 disposed over the middle layer 1310. The resist layer 1306 may be formed by any suitable process, such as a spin-on coating. The bottom layer 1310 may be a bottom anti-reflective coating (BARC) layer. The bottom layer 1308 may include or be a carbon backbone polymer or a silicon-free material formed by a spin-on coating process, a CVD process, a FCVD process, or any suitable deposition technique. The middle layer 1310 may be a silicon-containing inorganic polymer that provides anti-reflective properties and/or hard mask properties for a photolithography process. The middle layer 1310 may include or be amorphous silicon, silicon carbide, silicon nitride, silicon oxynitride, silicon oxide, a silicon-containing inorganic polymer, or any combination thereof. The photoresist top layer 1312 may be a DUV resist (KrF) resist, an argon fluoride (ArF) resist, an EUV resist, an electron beam (e-beam) resist, or an ion beam resist.

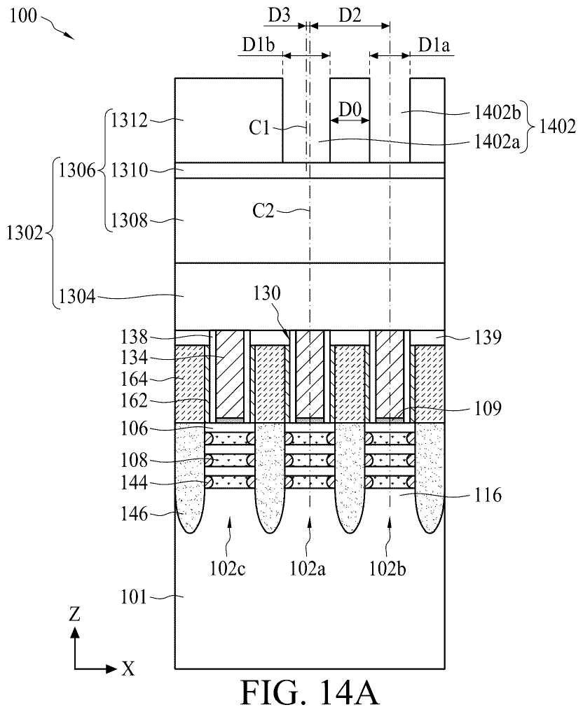

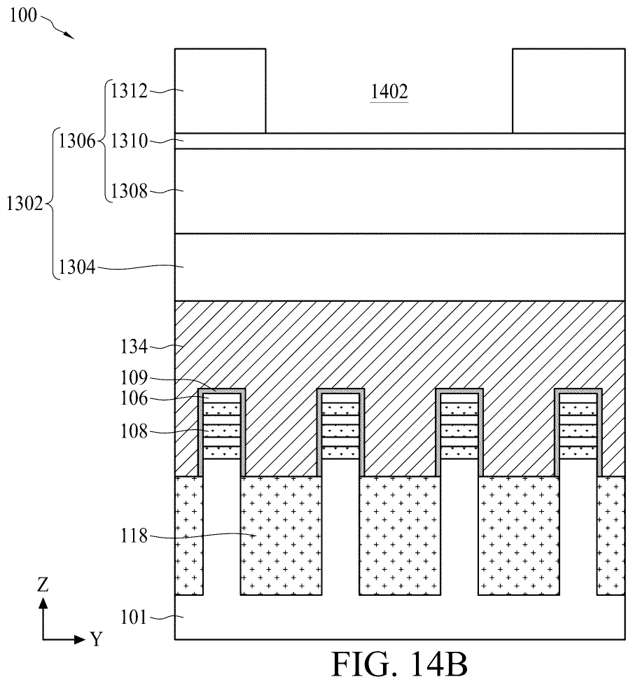

In FIGS. 14A and 14B, the photoresist top layer 1312 is patterned to form a plurality of photoresist mandrels separated from each other by an opening 1402. Each photoresist mandrel has a spacing or pitch (DO), which may vary depending on the pattern layout. For case of illustration, only two opening 1402a, 1402b are shown. The openings 1402 are arranged at locations where a portion of the sacrificial gate structures 130 may be revealed in a later stage. In some embodiments, each of the openings 1402 may extend to overlap a single sacrificial gate structure 130. In some embodiments, the opening 1402 may extend to overlap a plurality of sacrificial gate structures 130 along the X direction.

The patterned photoresist top layer 1312 is used as a mask during a subsequent process, such as one or more photolithographic processes, to transfer the pattern (i.e., openings 1402) in the photoresist top layer 1312 into the middle layer 1310, the bottom layer 1308, and the mask layer 1304. Under aggressive scaling requirement (e.g., gates with a pitch size less than about 50 nm), smaller critical dimension (CD) of the pattern openings 1402 (i.e., ADI CD, such as Dla, Dlb) is usually necessary to avoid peeling of the photoresist mandrels, which may otherwise lead to mis-alignment of the pattern and high risk of undercutting of the epitaxial source/drain features. In general, the ADI CD (Dla, Dlb) should be equal to or less than half of the pitch size D2 (e.g., center-to-center distance between two adjacent gates) to avoid peeling of the photoresist mandrels. The peeling of the photoresist mandrels may occur if the ADI CD (Dla, Dlb) is greater than the spacing (DO) of the photoresist mandrel. If the ADI CD (Dla, Dlb) is less than the spacing (DO) of the mandrel, the photoresist scum defects may occur.

For regions having less pattern density (e.g., an isolated pattern region), the peeling of the photoresist mandrels can be ameliorated by adjusting the ADI CD (D1a, D1b). The term “isolated pattern region” refers to regions in which a fin structure is distanced from another fin structure in the Y-direction by a minimum distance of 500 nm, such as 1000 nm or 10,000 nm. High peeling risk of the photoresist mandrels is often observed in the regions having greater pattern density (e.g., a dense pattern region) or semi-isolated pattern regions where a dense pattern region is immediately adjacent to, or located between two neighboring isolated pattern regions. The term “dense pattern region” refers to regions in which a fin structure is distanced from another fin structure in the Y-direction by a maximum distance of 100 nm, such as 60 nm or 40 nm. For example, the spacing or pitch (DO) may be no more than 100 nm, such as no more than 60 nm, or no more than 40 nm. Various embodiments of the present disclosure can mitigate or avoid peeling of the photoresist mandrels in the semi-isolated pattern regions so that the subsequent CPODE structures are formed without undercutting the epitaxial source/drain features.

The openings 1402 define locations of CPODE structures to be formed in the substrate portion of the fin structures 102a, 102b of a semi-isolated pattern region, for example. The semi-isolated pattern region may have two neighboring fin structures (which forms a dense pattern region) disposed adjacent to an isolated pattern region. In such cases, the opening 1402a may be used to form a long isolation trench over the substrate portion of the fin structure 102a, and the opening 1402b may be used to form a short isolation trench over the fin structure 102b, or vice versa. In some embodiments, the opening 1402a may be used to form a long isolation trench over the substrate portion of the fin structure 102a, and the opening 1402b may be used to form a long isolation trench over the substrate portion of the fin structure 102b. In some embodiments, the opening 1402a may be used to form a short isolation trench over the substrate portion of the fin structure 102a, and the opening 1402b may be used to form a short isolation trench over the substrate portion of the fin structure 102b. A long isolation trench may extend a first distance over a plurality of fin structures along a Y-direction, and a short isolation trench may extend a second distance over one or more fin structures along a Y-direction, wherein the second distance is shorter than the first distance. Various embodiments of the semi-isolated pattern region will be discussed in more detail below in FIGS. 20-1 to 20-3, 22-1 to 22-3, 23-1 to 23-5, and 24-1 to 24-3.

In any case, the photoresist top layer 1312 is patterned such that the hard mask pattern (i.e., pattern in the hard mask 1304) of an isolation trench (e.g., a CPODE structure) beneath the opening 1402a or the opening 1402b is shifted away outwardly from the center of the sacrificial gate structure 130. Additionally or alternatively, the photoresist top layer 1312 is patterned such that the hard mask patterns of both isolation trenches beneath the openings 1402a and the opening 1042b are shifted away from each other with respect to the respective sacrificial gate structure 130.

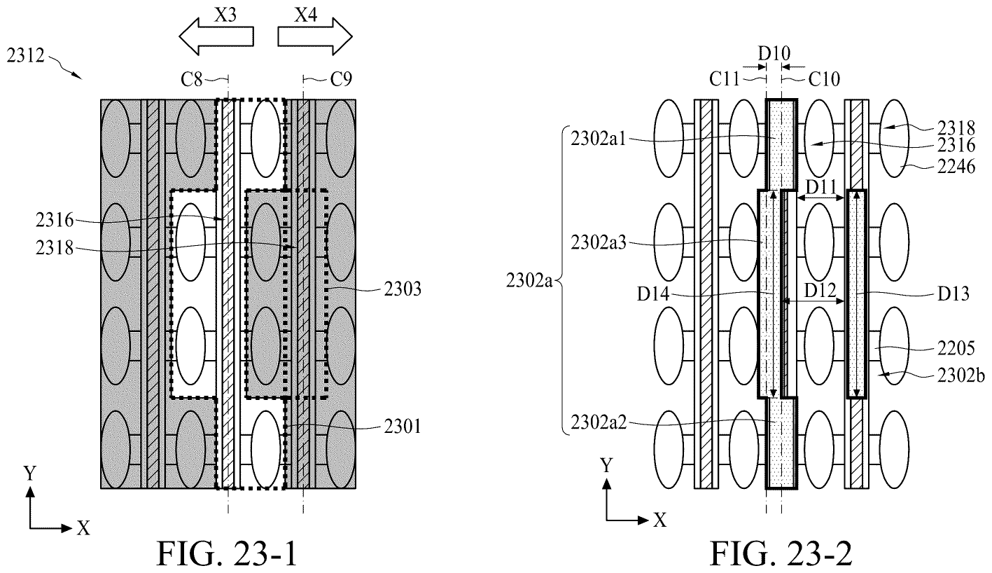

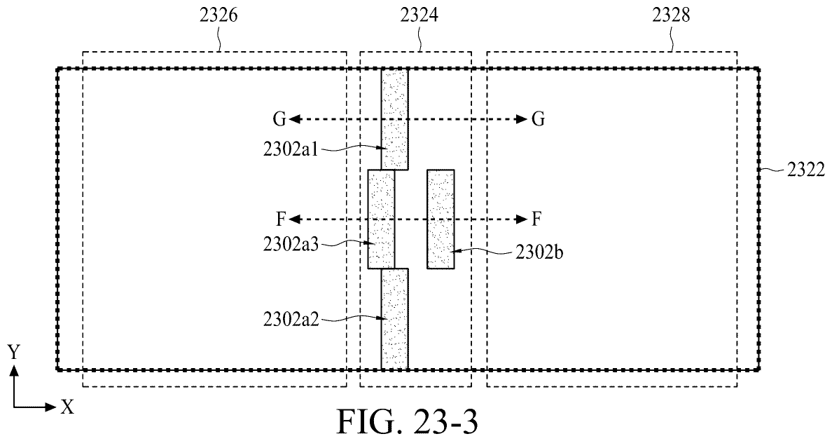

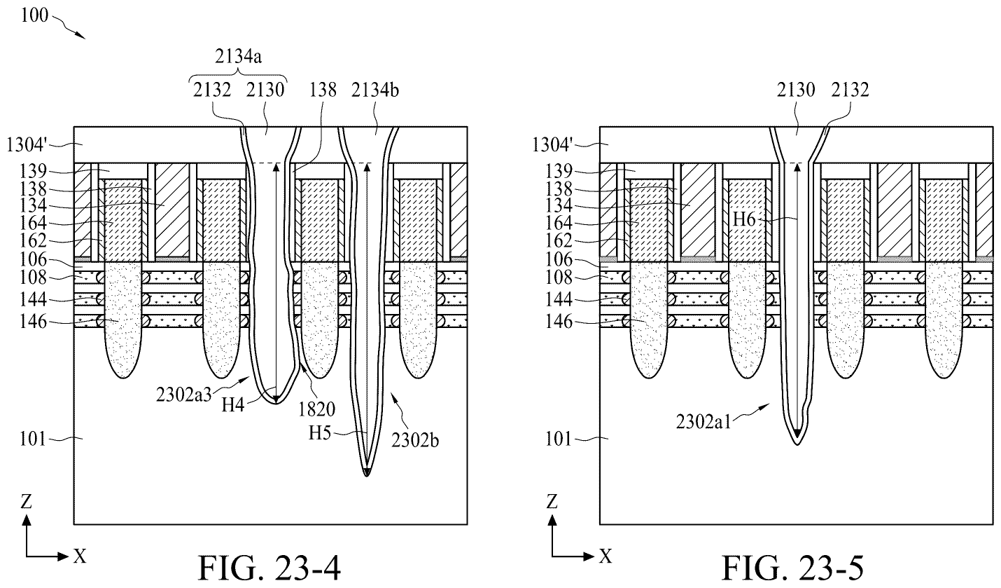

In the embodiment shown in FIG. 14A, the opening 1402a is used to form a long isolation trench and the opening 1402b is used to form a short isolation trench. The center of the opening 1402b is aligned with the center of the sacrificial gate structure 130 underneath the opening 1402b, i.e., the sacrificial gate structure 130 over the fin structure 102b. However, the opening 1402a is intentionally shifted to the left along the direction of arrow X, which is away from the opening 1402b. Particularly, the opening 1402a is shifted so that an imaginary line C1 passing through the center of the opening 1402a and an imaginary line C2 passing through the center of the sacrificial gate structure 130 are laterally offset from each other by a distance D3. That is, the opening 1402a and the sacrificial gate structure 130 over the substrate portion of the fin structure 102a are not aligned. In some embodiments, a portion of the opening 1402a may be shifted away from the opening 1402b. In such cases, a section of the opening 1420a immediately adjacent to and overlapping with the opening 1402b along the Y-direction is shifted away from the opening 1402b, as an exemplary embodiment shown in FIG. 23A.

The shift of the opening 1402a may be done through a pre-defined pattern in a photomask. The photomask may be an opaque plate or film with transparent areas that allow light to shine through in the pre-defined pattern on the photomask. The pre-defined pattern for the opening 1402a is configured to be shifted away from the imaginary line C2 passing through the center of the sacrificial gate structure 130. As a result, the pre-defined pattern is transferred to the photoresist top layer 1312 with the opening 1402a that is away from the center of the sacrificial gate structure 130, and therefore, away from the pattern of the opening 1402b. In any case, the distance D3 should be controlled so that the subsequent isolation trench formed in the substrate portion of the fin structure 102a has no or minimum impact to the epitaxial source/drain feature 146.

As will be discussed in more detail below, the isolation trenches may be formed by performing a fin-cut (or sheet-cut) process and filling the fin-cut (or sheet-cut) regions with a dielectric. This fin-cut (or sheet-cut) process may be referred to continuous-poly-on-diffusion edge (CPODE) process. The term “diffusion edge” is equivalently referred to as an active edge, which is an edge abutting adjacent active regions. The term “active region” refers to a region where transistors are formed. The CPODE process can be used to reduce gate pitch, thereby increasing the density for multi-gate devices and thus device performance required for aggressively scaled circuits and devices.

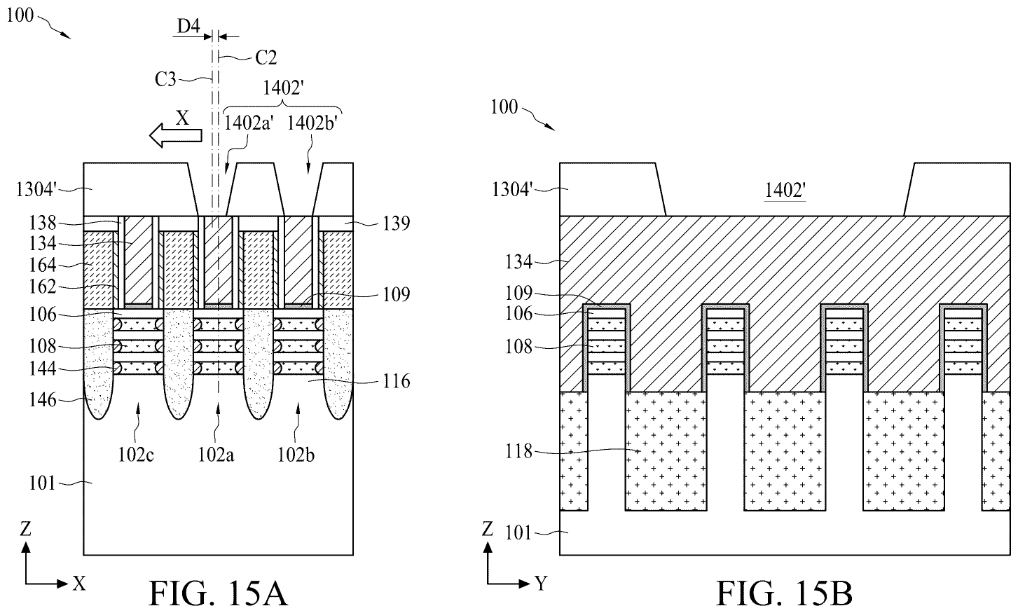

In FIGS. 15A and 15B, the patterns (i.e., openings 1402) in the photoresist top layer 1312 (FIGS. 14A and 14B) are transferred to the mask layer 1304 to form patterned mask layer 1304′. The bottom layer 1308, the middle layer 1310, the photoresist top layer 1312 are then removed. The formation of the patterned mask layer 1304′ may be achieved by one or more photolithographic processes. As a result of the one or more photolithographic processes, portions of the hard mask 1304 are removed, and trench patterns 1402a′, 1402b′ (collectively referred to as trench pattern 1402′) are formed in the patterned mask layer 1304′, and a portion of the sacrificial gate electrode layer 134 is exposed. The removal of portions of the hard mask 1304 (and native oxide formed thereon) may be performed using an etch chemistry, such as CF₄, CHF₃, CH₂F₂, CHF₃, C₄F₆, or the like. Due to the shift of the opening 1402a in the photoresist top layer 1312, the trench pattern 1402a′ in the hard mask 1304 is formed in an offset manner relative to the center of the sacrificial gate structure 130. Particularly, the trench pattern 1402a′ is formed so that an imaginary line C3 passing through the center of the trench pattern 1402a′ and the imaginary line C2 passing through the center of the sacrificial gate structure 130 are laterally offset from each other by a distance D4. That is, the trench pattern 1402a′ and the sacrificial gate structure 130 over the substrate portion of the fin structure 102a are not aligned. The trench pattern 1402b′, on the other hand, is aligned with the sacrificial gate structure 130 over the fin structure 102b. The trench pattern 1402a′ exposes a portion of the top surface of the sacrificial gate electrode layer 134 over the substrate portion of the fin structure 102a, while the trench pattern 1402b′ exposes entire or the majority of the top surface of the sacrificial gate electrode layer 134 over the fin structure 102b.

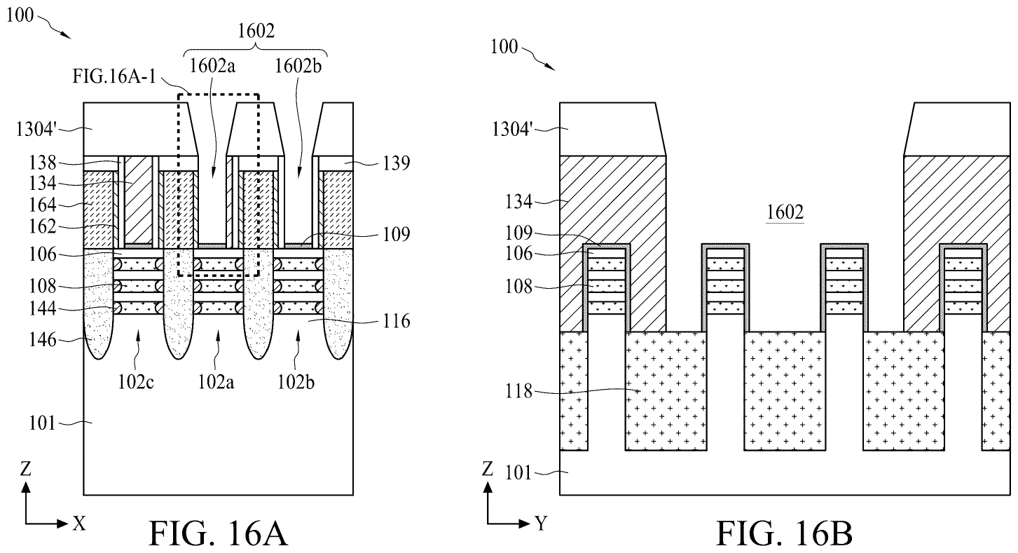

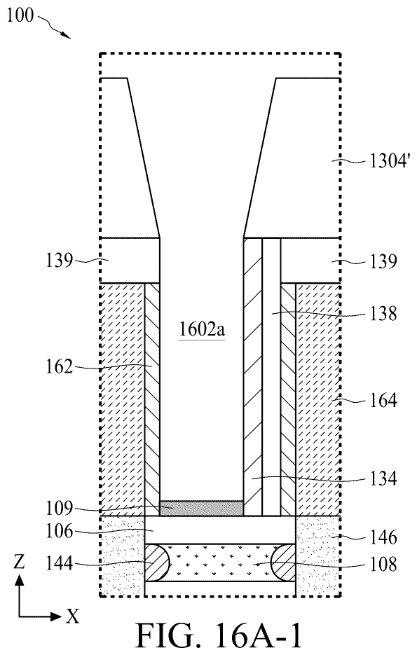

In FIGS. 16A and 16B, the exposed sacrificial gate structures 130 are selectively removed to form openings 1602a, 1602b (collectively referred to as openings 1602). The openings 1602 expose the cap layer 139, the CESL 162, the gate spacers 138 in the semi-isolated pattern regions. The removal of the exposed sacrificial gate structures 130 may be performed using any suitable etch back process. The etch back process may be a selective etch process that removes the sacrificial gate structures 130 but does not substantially affect the liner 109. The liner 109 protects the first and second semiconductor layers 106, 108 during the etch back process. The etch back process may be a dry etch, a wet etch, or a combination thereof. In some embodiments, a wet etchant such as a tetramethylammonium hydroxide (TMAH) solution is used to selectively remove the sacrificial gate electrode layer 134 but not the gate spacers 138, the cap layer 139, the ILD layer 164, and the CESL 162.

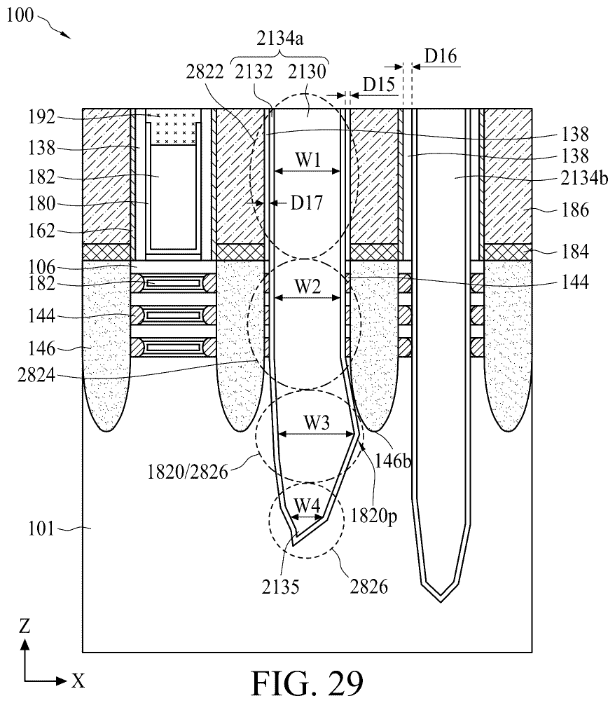

Due to the shift of the patterned opening 1402a, a portion of the sacrificial gate electrode layer 134 may not be removed effectively and remain within a recess under the shifted mask layer 1304′ on one side of the opening 1602a, as shown in FIG. 16A-1. The sacrificial gate electrode layer 134 stays in contact with the sidewall of the gate spacer 138, while the cap layer 139 and the CESL 162 on the other side of the opening 1602a are exposed. In some embodiments, the etch back process may not be effective such that a portion of the gate spacer 138 may still remain on one side of the opening 1602a. In such cases, the gate spacer 138 adjacent a first side of the opening 1602a may have a first thickness (e.g., D15 in FIG. 29) and the gate spacer 138 adjacent a second side of the opening 1602a may have a second thickness (e.g., D17 in FIG. 29) that is less than the first thickness.

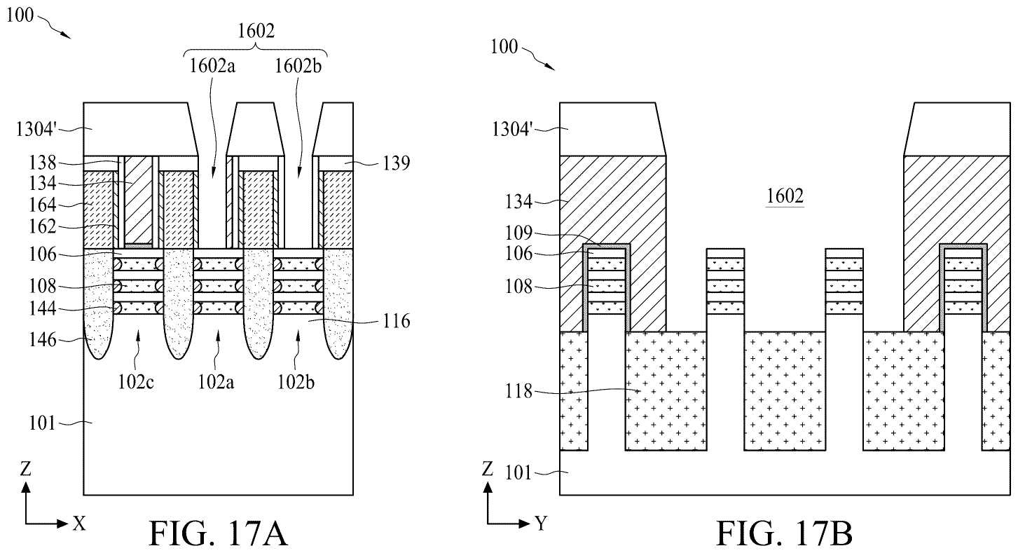

In FIGS. 17A and 17B, an etch process is performed to remove the liner 109. The etch process may be a dry etch, a wet etch, or a combination thereof. The etch process selectively removes the liner 109 without affecting the first and second semiconductor layers 106, 108, as well as the sacrificial gate electrode layer 134.

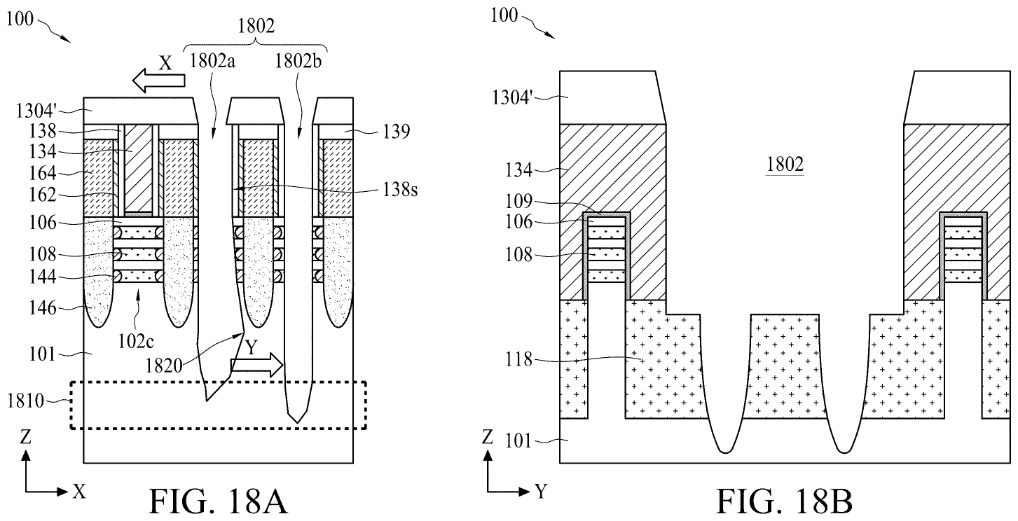

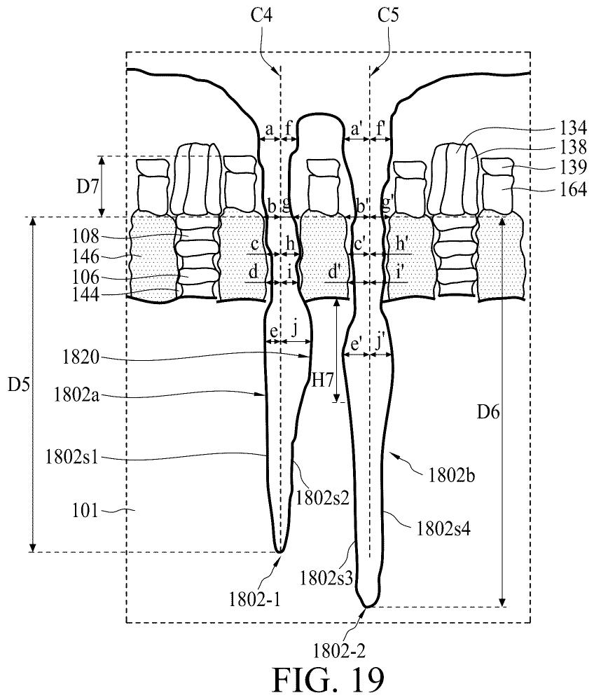

In FIGS. 18A and 18B, a fin-cut (or sheet-cut) process is performed to remove the first and second semiconductor layers 106, 108 at the semi-isolated pattern regions. The fin-cut process is performed using the patterned and shifted mask layer 1304′ as an etching mask. The fin-cut process may be dry etch, reactive ion etch (RIE), and/or other suitable processes. The fin-cut process is performed so that the exposed first semiconductor layers 106, the second semiconductor layers 108, and portions of the substrate 101 forming the fin structures 102a, 102b are selectively removed. A portion of the insulating material 118 around the fin structures 102a, 102b is also removed. A portion of the sacrificial gate electrode layer 134 remains at the sidewall 138s of the gate spacer 138 at one side of the isolation trench 1802a may also be removed during the fin-cut process. As a result of the fin-cut process, isolation trenches 1802a, 1802b (collectively referred to as isolation trenches 1802) are formed and extended into portions of the substrate 101 forming the fin structures 102a, 102b (FIG. 17A). The isolation trenches 1802 are to be filled with a dielectric material and form CPODE structures, which can block the path of leakage current through epitaxial source/drain features, transistors, and silicon substrates.

In some embodiments, the removal of the exposed first semiconductor layers 106, the second semiconductor layers 108, and portions of the substrate 101 is achieved using a self-aligned CPODE etch process (RCP). The self-aligned CPODE etch process is selected to have high etch selectivity so that the etch rate of the first and second semiconductor layers 106, 108 is greater than the etch rate of the inner spacers 144. As a result, the inner spacers 144 and therefore the epitaxial source/drain features 146 remain substantially intact after the fin-cut process. The isolation trenches 1802 (and thus subsequent CPODE structures) are formed with a depth sufficient to block leakage current, which may otherwise flow through epitaxial source/drain features, transistors, and silicon substrates.

In various embodiments, the fin-cut process is performed such that the isolation trench 1802a is formed with an asymmetric profile and the isolation trench 1402b′ has a substantially symmetric profile from top to bottom. In cases where the isolation trench 1802a is a long isolation trench and the isolation trench 1802b is a short isolation trench, the bottom of the isolation trench 1802a may be at a level higher than the bottom of the isolation trench 1802b due to different etch loading effects between the long isolation trench and the short isolation trench as well as different etching biases from environment pattern variations. Particularly, the isolation trench 1802a is formed in an asymmetric tapering manner with respect to an imaginary line passing through a center of the isolation trench 1802a in the depth direction of the isolation trench 1802a, while the isolation trench 1802b is formed in a symmetric tapering manner with respect to an imaginary line passing through a center of the isolation trench 1802b in the depth direction of the isolation trench 1802b. The lower portion of the isolation trench 1802a has a bowing profile 1820 extending in a direction (along the direction of arrow Y) opposite to the shifting direction (along the direction of arrow X) of the trench pattern 1402a′ (FIG. 15A). The term “bowing” refers to an aperture within the isolation trench 1802a having a larger diameter than the diameter of the trench pattern 1402a′. The bowing profile is extended outwardly from one side of the isolation trench 1802a to form a convex or curved profile. The bowing profile may be a result of asymmetric scattering of ions in the very narrow etched space of the isolation trench 1802a. Due to the shifted mask layer 1304′, a portion of the sacrificial gate electrode layer 134 may not be removed effectively and remain at the sidewall 138s of the gate spacer 138 at one side of the isolation trench 1802a, as discussed above with respect to FIG. 16A-1. In cases where RIE is used to perform the fin-cut process, the remaining sacrificial gate electrode layer 134 within the opening 1602a (FIG. 16A) would cause the highly selective plasma ions to deflect and scatter in an asymmetric manner, resulting in the bowing profile at or near the bottom of the isolation trench 1802a.

The high selectivity of the self-aligned CPODE etch process can be achieved using a bromine-based etch chemistry (e.g., HBr) and an oxygen-based chemistry (e.g., O₂ or CO₂). To further increase the selectivity of silicon over the hard mask (e.g., SiN), the patterned mask layer 1304′ may be exposed to a gas mixture comprising C—H based chemistry in the beginning of the self-aligned CPODE etch process to form a polymer protection layer (not shown) on exposed surfaces of the patterned mask layer 1304′. The polymer protection layer minimizes the patterned mask layer 1304′ from being damaged during the fin-cut process. Additionally or alternatively, an oxide-based passivation layer may be formed over the exposed surfaces of the patterned mask layer 1304′ to facilitate the self-aligned CPODE etch process. In such cases, a break-through etch process using C—H and/or C—F based chemistries may be used to etch the excessive passivation layer in the etch front. Suitable C—H and C—F based chemistries may include, but are not limited to CF₄, CHF₃, CH₂F₂, CHF₃, C₄F₆, or the like. The break-through etch process may also be utilized in the beginning of removing the mask layer 1304′ and/or after the insulating material 118 is partially removed and by-products are accumulated at the exposed sidewalls of the insulating material 118.

An exemplary self-aligned CPODE etch process may utilize an ICP/resonant antenna plasma source driven by an RF power generator using an AC electrical current operating on a tunable frequency of multiple of 13.56 MHz or 27 MHz. The process chamber may be operated at a pressure in a range of about 1 mTorr to about 200 mTorr and a temperature of about 10 degrees Celsius to about 200 degrees Celsius. The RF power generator is operated to provide source power between about 0 W to about 2500 W. The source power is used to form a plasma from HBr, O₂, and Ar (plasma etching step) and CF₄ and Ar (break-through step). An RF bias power operating in a range of about 0 W to about 2000 W is applied to the pedestal. In some cases, a pulse plasma etch may be used. In such cases, the output of the power generator may be controlled by a pulse signal having a duty cycle in a range of about 5% to 95%. Alternatively, the self-aligned CPODE etch process may use bias power only (with zero source power).

In some alternative embodiments, the fin-cut process is a multi-step process using a first etch scheme and a second etch scheme. The first etch scheme may be a plasma-based etch process employing one or more etchants that selectively remove the first and second semiconductor layers 106, 108 (and portions of the patterned mask layer 1304′) but do not substantially remove the sacrificial gate electrode layer 134. The first etch scheme may continue until the isolation trenches 1802 reach a depth defined by the top surface of the insulating material 118. In some cases, the first etch scheme may continue until a sidewall of the insulating material 118 is exposed.

Once the isolation trenches 1802 reach the desired depth needed for the first etch scheme, the second etch scheme is then performed to extend the isolation trenches 1802 into a desired depth below the bottom of the insulating material 118. In some embodiments, the bottom of the isolation trenches 1802 may be at an elevation into an accumulation region 1810 of the substrate 101. The term “accumulation region” refers to a non-conductive region in the substrate 101, which is below a depletion region (a conductive region located at/near the well portion 116 of the substrate 101). The second etch scheme may be a dry etch process employing one or more etchants that selectively remove the substrate 101 and a portion of the insulating material 118 but do not substantially remove the sacrificial gate electrode layer 134. The etchant used in the first etch scheme may be a chlorine-based etch chemistry, a bromine-based chemistry, or a chlorine/bromine-based etch chemistry. The etchant used in the second etch scheme may be a fluorine-based etch chemistry, a chlorine-based etch chemistry, a bromine-based etch chemistry, a fluorine/chlorine-based etch chemistry, a fluorine/bromine-based etch chemistry, a chlorine/bromine-based etch chemistry, or any combination thereof. In one exemplary embodiment, the first etch scheme employs a bromine-based etch chemistry and the second etch scheme employs a fluorine-based etch chemistry and a bromine-based etch chemistry, or vice versa. In another exemplary embodiment, the first etch scheme employs a bromine-based etch chemistry and the second etch scheme employs a bromine-based etch chemistry. Exemplary chlorine-based etch chemistry may include, but are not limited to, Cl₂, CHCl₃, CCl₄, BCl₃, or the like, or a combination thereof. Exemplary bromine-based etch chemistry may include, but are not limited to, HBr, Br₂, BBr₃, or the like, or a combination thereof. Exemplary fluorine-containing gas may include, but are not limited to, CF₄, SF₆, CH₂F₂, C₂H₄F₂, CHF₃, C₂F₆, or the like, or a combination thereof.

In some embodiments, after the first etch scheme and prior to the second etch scheme, the semiconductor device structure 100 may be exposed to a gas mixture comprising a silicon-containing precursor (e.g., SiCl₄), a bromine-containing precursor (e.g., HBr), and an inert gas (e.g., Ar), followed by an oxidation process, to form a silicon oxide layer on the exposed surfaces of the sacrificial gate electrode layer 134. The silicon oxide layer helps shrink the critical dimension (CD) of the openings 1602 so that the isolation trenches 1802 as formed are extended into the substrate portion of the fin structures 102a, 102b in the depletion region with a proper CD. In such cases, an etch process using etch chemistries comprising fluorine-containing gas (e.g., CF₄) and an inert gas (e.g., Ar) may be performed to break through the silicon oxide layer.

In some embodiments, the second etch scheme is a cyclic process including repetitions of a plasma etching step and a break-through step. The plasma etching step may use an inert gas (e.g., Ar), an oxygen-containing gas (e.g., O₂), and any of the etch chemistries (e.g., HBr) mentioned in the second etch scheme above and be configured to remove the substrate portion of the fin structures 102a, 102b. The break-through step may use an inert gas (e.g., Ar) and/or any of the etch chemistries (e.g., CF₄) mentioned in the second etch scheme above and configured to remove the substrate portion of the fin structures 102a, 102b, the insulating material 118, the silicon oxide layer (if any), and any debris/by-products formed during the plasma etching step. The plasma etching step may be performed for a first period of time (T1) and the break-through step may be performed for a second period of time (T2), and the ratio of T1:T2 may be about 3:1 to about 6:1. The cyclic process may be repeated 2 to 5 cycles. In some embodiments, the second etch process further includes an over-etch step following the cyclic process. The over-etch step may use an inert gas (e.g., Ar), an optional oxygen-containing gas (e.g., O₂), and any of the etch chemistries (e.g., HBr) mentioned in the second etch scheme above and be configured to remove additional portion of the substrate 101. An RF bias power may be supplied (to a pedestal upon which the semiconductor device structure 100 is disposed) during the first etch scheme, the plasma etching step of the second etch scheme, and the over-etch step to enable anisotropic etching. The use of the RF bias power also compensates for the etch selectivity needed for removing the insulating material 118 and the substrate portion of the fin structures 102a, 102b. With the use of the RF bias power and the cyclic process, the substrate portion of the fin structures 102a, 102b can be removed completely.

An exemplary process for the second etch scheme may utilize an ICP/resonant antenna plasma source driven by an RF power generator using a tunable frequency of about 13.56 MHz or about 27 MHz. The process chamber may be operated at a pressure in a range of about 1 mTorr to about 200 mTorr and a temperature of about 10 degrees Celsius to about 200 degrees Celsius. The RF power generator is operated to provide source power between about 0 W to about 2500 W. An RF bias power operating in a range of about 0 W to about 2000 W is applied to the pedestal during the second etch scheme. To enhance the directionality of the etch processes, only the bias power (with zero source power) may be used. In some cases, a pulse plasma etch process with a duty cycle in a range of about 5% to 95% may be used. The second etch scheme is a cyclic process including the plasma etching step (using HBr, O₂, and Ar) and a break-through step (using Ar and/or CF₄) is used. The over-etch step is a plasma etch process using HBr, O₂, and Ar.

FIG. 19 illustrates a schematic view of a portion of the semiconductor device structure 100 showing the isolation trenches 1802 of FIG. 18A after the self-aligned CPODE etch process, in accordance with some embodiments. As can be seen, the isolation trench 1802a extends a first depth into the substrate 101 and the isolation trench 1802b extends a second depth into the substrate 101, wherein the second depth is greater than the first depth. In some embodiments, the isolation trench 1802a has a height D5 measuring from a top surface of the epitaxial source/drain feature 146 to a bottom surface 1802-1 of the isolation trench 1802a, and the isolation trench 1802b has a height D6 measuring from the top surface of the epitaxial source/drain feature 146 to a bottom surface 1802-2 of the isolation trench 1802b, wherein the height D6 is greater than the height D5. In some embodiments, the height of each of the isolation trenches 1802 may be measured from the top surface of the cap layer 139. In such cases, the heights D5 and D6 of the isolation trenches 1802a, 1802b may further include the combined thickness of the cap layer 139 and the ILD layer 164, which have a height D7.

The isolation trench 1802a has an asymmetric trench profile in which the opposing sidewalls 1802s1 and 1802s2 of the isolation trench 1802a have unequal distance with respect to an imaginary line C4 passing through the center of the isolation trench 1802a. In some embodiments, a portion of the sidewall 1802sl above the cap layer 139 may have a distance “a” to the imaginary line C4 and a portion of the sidewall 1802s2 above the cap layer 139 may have a distance “f” to the imaginary line C4 that is less than the distance “a”.

In some embodiments, a portion of the sidewall 1802sl at or near the interface between the ILD 164 and the epitaxial source/drain feature 146 may have a distance “b” to the imaginary line C4 and a portion of the sidewall 1802s2 at or near the interface between the ILD 164 and the epitaxial source/drain feature 146 may have a distance “g” to the imaginary line C4 that is less than the distance “b”.

In some embodiments, a portion of the sidewall 1802sl at or near the middle portion of the epitaxial source/drain feature 146 may have a distance “c” to the imaginary line C4 and a portion of the sidewall 1802s2 at or near the middle portion of the epitaxial source/drain feature 146 may have a distance “h” to the imaginary line C4 that is greater than the distance “c”.

In some embodiments, a portion of the sidewall 1802sl at or near the bottom portion of the epitaxial source/drain feature 146 may have a distance “d” to the imaginary line C4 and a portion of the sidewall 1802s2 at or near the bottom portion of the epitaxial source/drain feature 146 may have a distance “i” to the imaginary line C4 that is greater than the distance “d”.

In some embodiments, a portion of the sidewall 1802sl at or near the bowing profile 1820 of the isolation trench 1802a may have a distance “e” to the imaginary line C4 and a portion of the sidewall 1802s2 at or near the bowing profile 1820 of the isolation trench 1802a may have a distance “j” to the imaginary line C4 that is greater than the distance “e”. In some embodiments, the distance “e” and the distance “j” have a ratio (e:j) in a range of about 1:1.5 to about 1:2.5, for example about 1:2.

In some embodiments, the bowing profile 1820 may have a height “H7” extending in the depth direction of the isolation trench 1802a, and the height “H7” is about 20% to about 50%, such as about 30% to 40% of the height D5 of the isolation trench 1802a.

The isolation trench 1802b has a symmetric trench profile in which the opposing sidewalls 1802s3 and 1802s4 of the isolation trench 1802b have equal distance with respect to an imaginary line C5 passing through the center of the isolation trench 1802b. In some embodiments, a portion of the sidewall 1802s3 above the cap layer 139 may have a distance “a″” to the imaginary line C5 and a portion of the sidewall 1802s4 above the cap layer 139 may have a distance “f″” to the imaginary line C5 that is substantially equal to the distance “a″”.

In some embodiments, a portion of the sidewall 1802s3 at or near the interface between the ILD 164 and the epitaxial source/drain feature 146 may have a distance “b″” to the imaginary line C5 and a portion of the sidewall 1802s4 at or near the interface between the ILD 164 and the epitaxial source/drain feature 146 may have a distance “g″” to the imaginary line C5 that is substantially equal to the distance “b″”.

In some embodiments, a portion of the sidewall 1802s3 at or near the middle portion of the epitaxial source/drain feature 146 may have a distance “c″” to the imaginary line C5 and a portion of the sidewall 1802s4 at or near the middle portion of the epitaxial source/drain feature 146 may have a distance “h″” to the imaginary line C5 that is substantially equal to the distance “c″”.

In some embodiments, a portion of the sidewall 1802s3 at or near the bottom portion of the epitaxial source/drain feature 146 may have a distance “d″” to the imaginary line C5 and a portion of the sidewall 1802s4 at or near the bottom portion of the epitaxial source/drain feature 146 may have a distance “I″” to the imaginary line C5 that is substantially equal to the distance “d″”.

In some embodiments, a portion of the sidewall 1802s3 below the bottom surface of the epitaxial source/drain feature 146 may have a distance “e″” to the imaginary line C5 and a portion of the sidewall 1802s4 below the bottom surface of the epitaxial source/drain feature 146 may have a distance “j″” to the imaginary line C5 that is substantially equal to the distance “e″”.

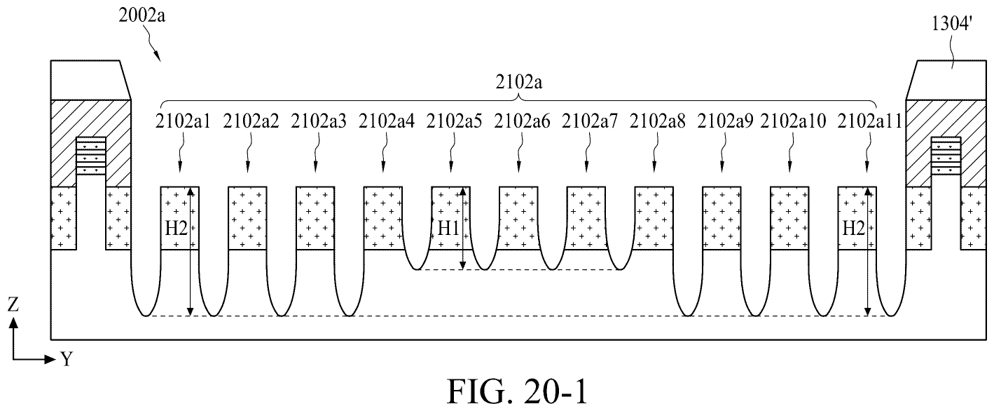

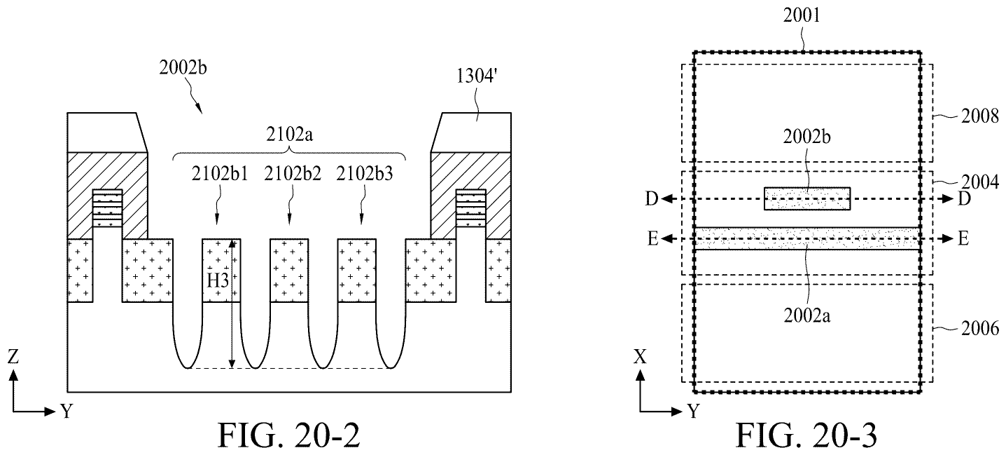

FIG. 20-1 is a cross-sectional view of a portion of fin structures 2102a selected for a long isolation trench 2002a in a semi-isolated pattern region 2001 taken along cross-section D-D of FIG. 20-3, in accordance with some embodiments. FIG. 20-2 is a cross-sectional view of a portion of fin structures 2102b selected for a short isolation trench 2002b in the semi-isolated pattern region 2001 taken along cross-section E-E of FIG. 20-3, in accordance with some embodiments. FIG. 20-3 is a top view of a portion of the semi-isolated pattern region 2001 having the long isolation trench 2002a and the short isolation trench 2002b, in accordance with some embodiments. In the semi-isolated pattern region 2001, the long isolation trench 2002a and the short isolation trench 2002b are disposed immediately adjacent to each other within a dense pattern region 2004, which is located between a first isolated pattern region 2006 and a second isolated pattern region 2008. The first isolated pattern region 2006 is disposed adjacent to the long isolation trench 2002a within the dense pattern region 2004, and the second isolated pattern region 2008 is disposed adjacent to the short isolation trench 2002b within the dense pattern region 2004.

In some embodiments, the long isolation trench 2002a in the semi-isolated pattern region 2001 may extend to cover a plurality of fin structures, such as fin structures 2102a1 to 2102a11 as shown in FIG. 20-1, and the short isolation trench 2002b in the semi-isolated pattern region 2001 may extend to cover a plurality of fin structures, such as fin structures 2102b1, 2102b2, 2102b3 as shown in FIG. 20-2. In cases where a photomask layer (e.g., mask layer 1304′ in FIG. 15A) for the long isolation trench 2002a is configured to shift away from the short isolation trench 2002b, the fin structures 2102a1 to 2102a11 selected for the long isolation trench 2002a may have various heights due to different etch loading effects between the long isolation trench 2002a and the short isolation trench 2002b and the pattern density change in the area. In addition, with the loading effect due to environment pattern variations, the isolated and dense patterns can have different etching biases, causing the trench openings within the long isolation trench 2002a to have different depths. For example, the fin structures 2102a9, 2102a10, 2102a11 selected for the long isolation trench 2002a may be disposed immediately adjacent to the fin structures 2102b1, 2102b2, 2102b3 selected for the short isolation trench 2002b. In such cases, the fin structures 2102a5, 2102a6, 2102a7 may have a height H1, the fin structures 2102a1, 2102a2, 2102a3, 2102a9, 2102a 10, 2102a11 may have a height H2 that is greater than the height H1. The difference between the heights H1 and H2 may result in the substrate 101 with a step-like profile when viewing along the Y-direction. The fin structures 2102b1, 2102b2, 2102b3 selected for the short isolation trench 2002b may have a height H3 that is greater than the height H2.

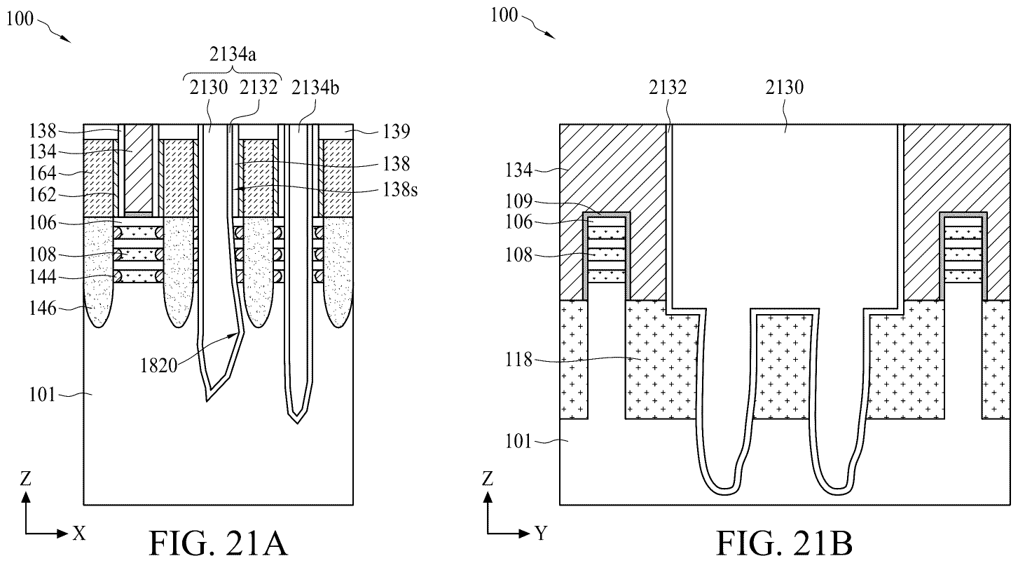

FIGS. 21A and 21B, the isolation trenches 1802 are filled with a dielectric material 2130. In some embodiments, a dielectric liner 2132 may be disposed between the dielectric material 2130 and the exposed surfaces of the isolation trenches 1802a. In some embodiments, a portion of the sacrificial gate electrode layer 134 (not shown) may be left between and in contact with the dielectric liner 2132 and the gate spacer 138 at one side of the isolation trench 1802. The dielectric material 2130 and the dielectric liner 2132 filled within the isolation trenches 1802 (e.g., isolation trench 1802a) form an isolation trench structure 2134a. The dielectric material 2130 and the dielectric liner 2132 filled within the isolation trenches 1802 (e.g., isolation trench 1802b) form an isolation trench structure 2134b. The dielectric material 2130 and the dielectric liner 2132 may be made of an oxygen-containing material, such as silicon oxide (SiO₂); a nitrogen-containing material, such as silicon nitride, silicon oxynitride (SiON), SiOCN, SiCN; a low-K dielectric material; or any suitable dielectric material. The dielectric material 2130 may include a material chemically different than the and the dielectric liner 2132, and may be formed by any suitable process, such as a CVD, PECVD, FCVD, or ALD process. Once the isolation trenches 1802 are filled, a planarization process, such as a CMP process, may be performed to remove portions of the dielectric material formed over the patterned mask layer 1304′. The planarization process is performed until a portion of the cap layer 139 or the sacrificial gate electrode layer is exposed. The isolation trench structures 2134a extend through the depletion region and into the accumulation region 1810 (FIG. 18A) of the substrate 101 to block the leakage current path that may otherwise form through epitaxial source/drain features, transistors, and silicon substrates.

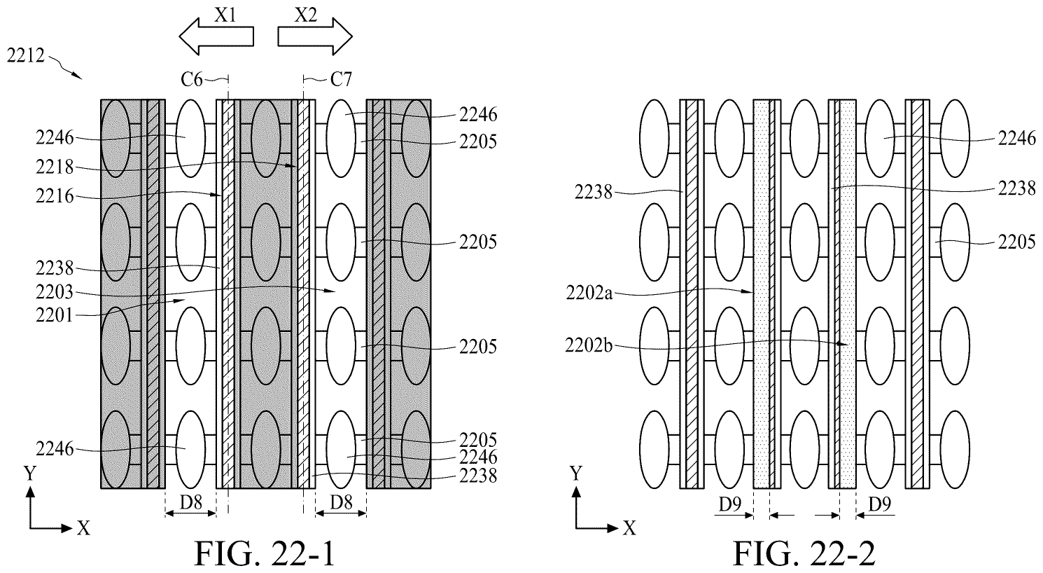

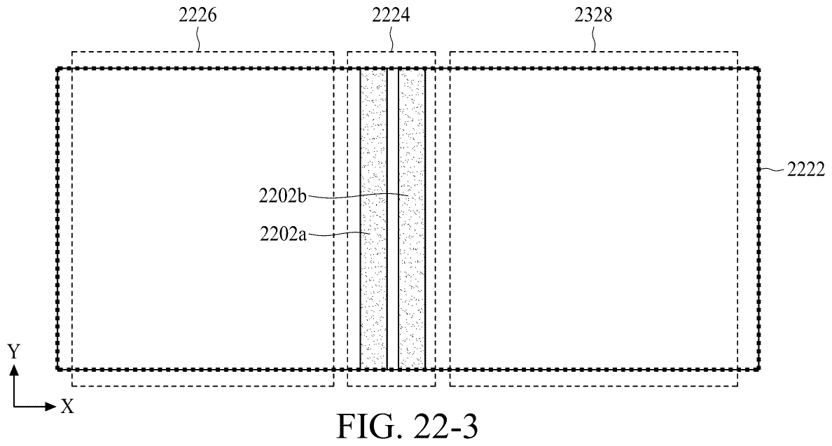

FIG. 22-1 is a schematic top view of a portion of a patterned photoresist top layer 2212 (e.g., photoresist top layer 1312 in FIG. 14A) having openings 2201, 2203 for forming long isolation trench structures 2202a, 2202b of FIG. 22-3, in accordance with some embodiments. FIG. 22-2 is a schematic top view of a portion of the long isolation trench structures 2202a, 2202b using the patterned photoresist top layer 2212 of FIG. 22-1 as an etching mask. FIG. 22-3 is a schematic top view of a semi-isolated pattern region 2222 having a dense pattern region 2224 disposed between a first isolation region 2226 and a second isolation region 2228. In FIG. 22-1, the opening 2201 is formed across a portion of each of a plurality of fin structures 2205 along the Y-direction to provide the long isolation trench structure 2202a (FIG. 22-3), and the opening 2203 is formed across a portion of each of the plurality of fin structures 2205 along the Y-direction to provide the long isolation trench structure 2202b (FIG. 22-3). Due to etch bias differences (i.e., the bias between ADI (After Development Inspection) CD (Critical Dimension) and AEI (After Etch Inspection) CD), the openings 2201, 2203 may have a first critical dimension D8, and the isolation trench structures 2234a, 2234b may have a second critical dimension D9 that is less than the first critical dimension D8. The openings 2201, 2203 are shifted away in a manner as discussed above with respect to FIGS. 14A and 14B. In some embodiments, the opening 2201 is shifted away from an imaginary line C6 passing through a sacrificial gate structure 2216 along the direction of arrow X1, while the opening 2203 is shifted away from an imaginary line C7 passing through a sacrificial gate structure 2218 along the direction of arrow X2. The shifted openings 2201, 2203 ensure the patterned photoresist top layer 2212 between the openings 2201, 2203 is formed with a sufficient thickness, thereby avoiding peeling of the photoresist mandrels.

Alternatively, the opening 2201 may be shifted away from an imaginary line C6 passing through the center of a sacrificial gate structure 2216 along the direction of arrow X1, while the opening 2203 is aligned with the imaginary line C7 passing through the sacrificial gate structure 2218. Alternatively, the opening 2201 is aligned with the imaginary line C6 passing through the center of the sacrificial gate structure 2216, while the opening 2203 may be shifted away from the imaginary line C7 passing through the sacrificial gate structure 2218 along the direction of arrow X2. Alternatively, both the openings 2201, 2203 may be shifted away from each other with respect to its respective center line C6, C7.

While the shifted openings 2201, 2203 may cause the patterned hard mask (e.g., patterned hard mask 1304′ shown in FIG. 18A) to shift and overlap with a portion of the epitaxial source/drain features 2246 and gate spacers 2238 adjacent to the sacrificial gate structure 2216 and/or sacrificial gate structure 2218, the self-aligned CPODE etch process as discussed above with respect to FIGS. 18A and 18B can be used to form the isolation trench structures 2202a, 2202b without damaging the epitaxial source/drain features.

FIG. 23-1 is a schematic top view of a portion of a patterned photoresist top layer 2312 (e.g., photoresist top layer 1312 in FIG. 14A) having openings 2301, 2303 for forming a long isolation trench structure 2302a and a short isolation trench structure 2302b of FIG. 23-3, in accordance with some embodiments. FIG. 23-2 is a schematic top view of a portion of long and short isolation trench structures 2302a, 2302b formed using the patterned photoresist top layer 2312 of FIG. 23-1 as an etching mask. FIG. 23-3 is a schematic top view of a semi-isolated pattern region 2322 having a dense pattern region 2324 disposed between a first isolation region 2326 and a second isolation region 2328. The embodiments of FIGS. 23-1 to 23-3 are similar to the embodiments of FIGS. 22-1 to 22-3 except that both long and short isolation trench structures 2302a, 2302b are included in the semi-isolation region 2324. In some embodiments, a portion of the opening 2301 in the photoresist top layer 2312 is shifted away from an imaginary line C8 passing through a sacrificial gate structure 2316 along the direction of arrow X3, and the opening 2303 in the photoresist top layer 2312 is aligned with an imaginary line C9 passing through a sacrificial gate structure 2318. In some embodiments, the portion of the opening 2301 immediately adjacent to and overlapping in the longitudinal direction (i.e., Y-direction) of the sacrificial gate structure 2316 with the opening 2303 is shifted. Alternatively, a portion of the opening 2301 in the photoresist top layer 2312 is aligned with the imaginary line C8, and the opening 2303 in the photoresist top layer 2312 is shifted away from the imaginary line C9 along the direction of arrow X4, resulting in shift of a portion of the short isolation trench structure 2302b away from the long isolation trench structure 2302a. In either case, the outward shifting of the opening 2301 ensures a thicker mandrel of the patterned photoresist top layer 2312 to leave between the openings 2301 and the opening 2303 after the photo-lithography and etching processes. As a result, the peeling of the photoresist mandrels is avoided. In addition, shifting of a portion of the opening 2301 allows the subsequent CPODE trench structures to be formed without undercutting the epitaxial source/drain features, especially when a self-aligned CPODE etch process is adapted.

The outward shifting of the opening 2301 may result in shift of a portion of the long isolation trench structure 2302a away from the short isolation trench structure 2302b, as shown in FIG. 23-2. In some embodiments, the long isolation trench structure 2302a may include a first section 2302a1, a second section 2302a2, and a third section 2302a3 connecting the first and second sections 2302a1, 2302a2, and an imaginary line C10 passing through the center of the first and second sections 2302a1, 2302a2 and an imaginary line C11 passing through the center of the third section 2302a3 may be laterally offset from each other by a distance D10. Stated differently, the first and second sections 2302a1, 2302a2 are separated from the short isolation trench structure 2302b by a lateral distance D11, and the third section 2302a3 is separated from the short isolation trench structure 2302b by a lateral distance D12 that is greater than the distance D11.

In some embodiments, the first section 2302a1 may extend over a portion of a first fin structure 2205 along the Y-direction, the second section 2302a2 may extend over a portion of a second fin structure 2205 along the Y-direction, and the third section 2302a3 may extend a portion of a third and a fourth fin structures 2205 along the Y-direction. Likewise, the short isolation trench structure 2302b may extend a portion of the third and the fourth fin structures 2205 along the Y-direction. The third section 2302a3 of the long isolation trench structure 2302a has a first length D13 along the Y-direction and the short isolation trench structure 2302b has a second length D14 along the Y-direction, and the second length is substantially equal to the first length D13.

FIGS. 23-4 is a cross-sectional view of a portion of the semiconductor device structure 100 showing the long and short isolation trench structures 2302a, 2302b in the semi-isolated pattern region 2324 taken along cross-section F-F of FIG. 23-3, in accordance with some embodiments. FIGS. 23-5 is a cross-sectional view of a portion of the semiconductor device structure 100 showing the short isolation trench structures 2302b in the semi-isolated pattern region 2324 taken along cross-section F-F of FIG. 23-3, in accordance with some embodiments. As can be seen in FIGS. 23-4 and 23-5, the third section 2302a3 of the long isolation trench structure 2302a may have a height H4 measuring from a top surface of the cap layer 139 to a bottom of the long isolation trench structure 2302a, the short isolation trench structure 2302b may have a height H5 measuring from the top surface of the cap layer 139 to a bottom of the short isolation trench structure 2302b, and the first section 2302a1 of the long isolation trench structure 2302a may have a height H6 measuring from the top surface of the cap layer 139 to a bottom of the long isolation trench structure 2302a. As discussed above with respect to FIGS. 18A to 20-3, the different etch loading effects and environment pattern variations may result in the height H5 of the short isolation trench structure 2302b being greater than the height H4 of the third section 2302a3 of the long isolation trench structure 2302a. Likewise, the height H6 of first section 2302a1 of the long isolation trench structure 2302a is greater than the height H4 of the third section 2302a3 of the long isolation trench structure 2302a since the etchant used for forming the third section 2302a3 of the long isolation trench 2302a is further consumed by the gate spacers 138 due to the outward shifting of the opening in the patterned hard mask 1304′.

In some embodiments, the first section 2302a1 of the first isolation trench structure has a substantially symmetric profile in the depth direction of the long isolation trench structure 2302a, and the third section 2302a3 of the long isolation trench structure 2302a has an asymmetric profile with respect to an imaginary line passing through a center of the long isolation trench structure 2302a in the depth direction of the long isolation trench structure 2302a, and the short isolation trench structure 2302b has a symmetric profile with respect to an imaginary line passing through a center of the short isolation trench structure 2302b in the depth direction of the short isolation trench structure 2302b.

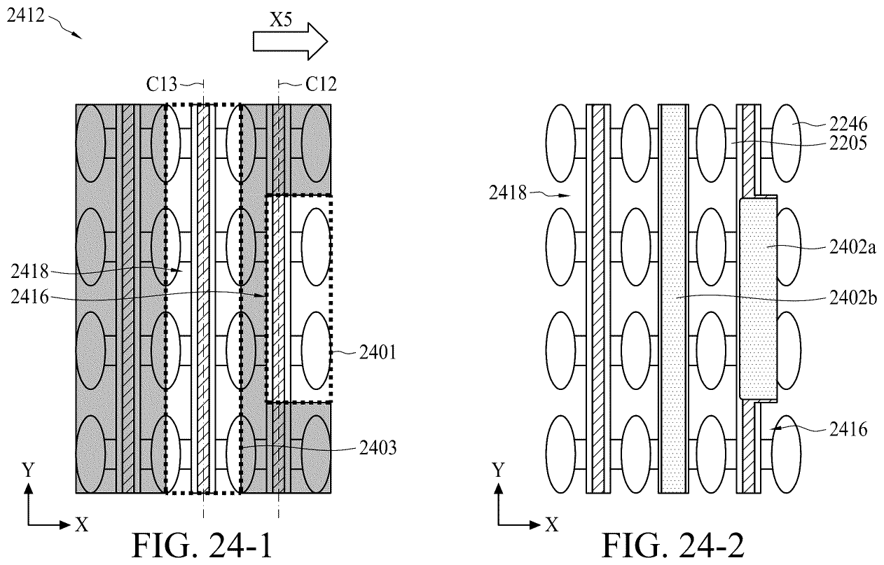

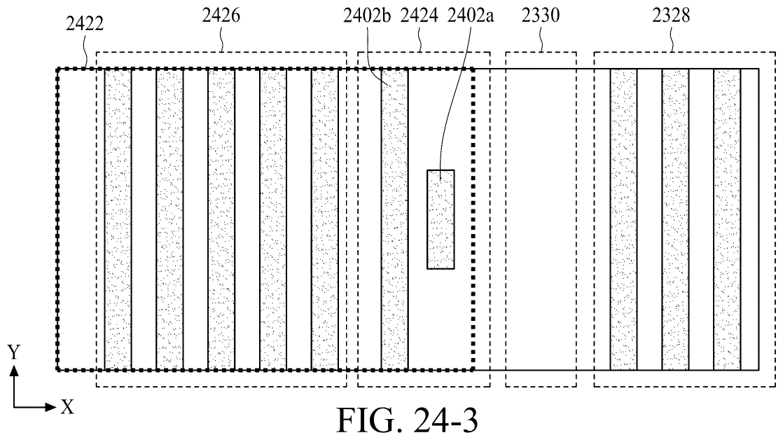

FIG. 24-1 is a schematic top view of a portion of a patterned photoresist top layer 2412 (e.g., photoresist top layer 1312 in FIG. 14A) having openings 2401, 2403 for forming a short isolation trench structure 2402a and a long isolation trench structure 2402b of FIG. 24-3, in accordance with some embodiments. FIG. 24-2 is a schematic top view of a portion of short and long isolation trench structures 2402a, 2402b formed using the patterned photoresist top layer 2412 of FIG. 24-1 as an etching mask. FIG. 24-3 is a schematic top view of a semi-isolated pattern region 2422 having a first dense pattern region 2424 having a first side adjacent to a second dense pattern region 2326, and a second side separated from a third dense pattern region 2328 by an isolated pattern region 2330.

In some embodiments, a portion of the opening 2401 in the photoresist top layer 2413 is shifted away from an imaginary line C12 passing through a sacrificial gate structure 2416 along the direction of arrow X5, and the opening 2403 in the photoresist top layer 2412 is aligned with an imaginary line C13 passing through a sacrificial gate structure 2418. The outward shifting of the opening 2401 ensures a thicker mandrel of the patterned photoresist top layer 2412 to provide between the openings 2401 and the opening 2403. As a result, the peeling of the photoresist mandrels is avoided.

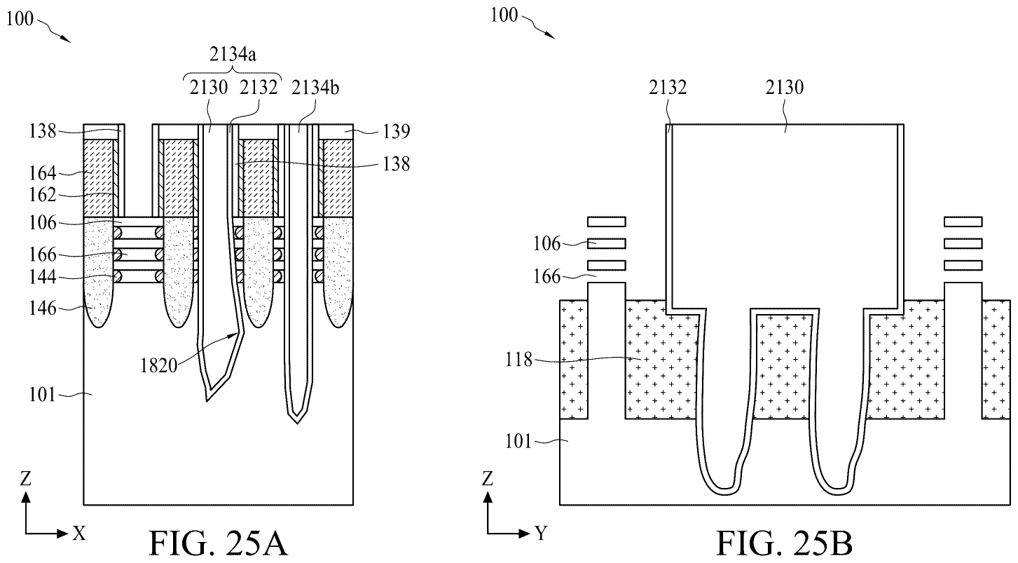

In FIGS. 25A and 25B, the sacrificial gate structures 130, the liner 109, and the second semiconductor layers 108 are removed. The removal of the sacrificial gate structures 130 and the semiconductor layers 108 forms an opening 166 between the first semiconductor layers 106. The cap layer 139, the CESL 162, and the ILD layer 164 protect the epitaxial source/drain features 146 during the removal processes. The sacrificial gate structures 130 can be removed using plasma dry etching and/or wet etching. In some embodiments, a wet etchant such as a tetramethylammonium hydroxide (TMAH) solution can be used to selectively remove the sacrificial gate electrode layer 134 and the liner 109 but not the gate spacers 138, the isolation trench structures 2134a, the ILD layer 164, and the CESL 162. After the removal of the sacrificial gate structures 130, the first semiconductor layers 106 and the inner spacers 144 are exposed to the opening 166.

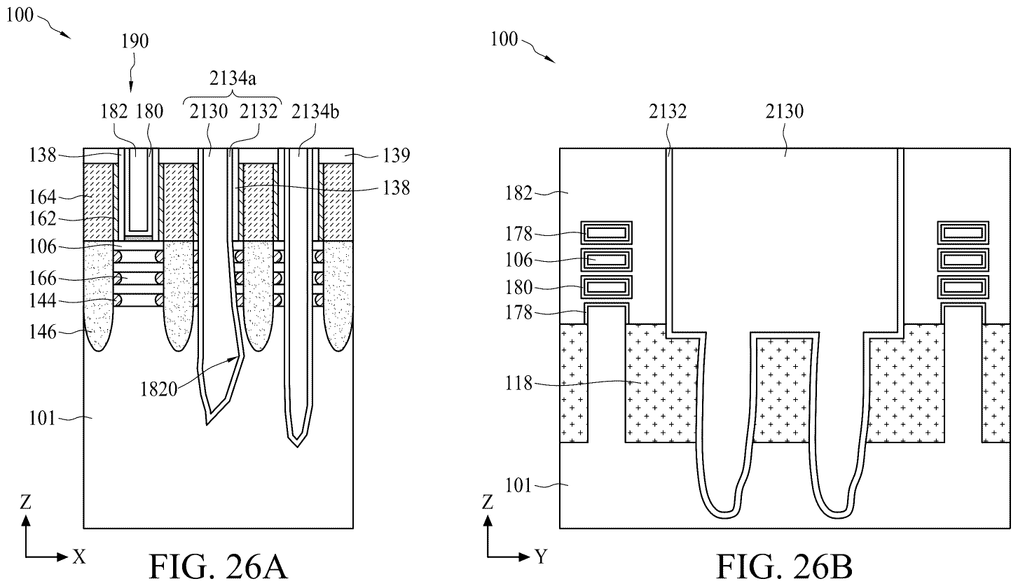

In FIGS. 26A and 26B, replacement gate structures 190 are formed. The replacement gate structures 190 may each include a gate dielectric layer 180 and a gate electrode layer 182. In some embodiments, an interfacial layer (IL) 178 may be formed between the gate dielectric layer 180 and the first semiconductor layer 106. The IL 178 may also form on the exposed surfaces of the substrate 101. The IL may include or be made of an oxide (e.g., silicon oxide) formed by thermal or chemical oxidation of the first semiconductor layers 106, a nitride (e.g., silicon nitride, silicon oxynitride, oxynitride, etc.), and/or a dielectric layer (e.g., hafnium silicate). Next, the gate dielectric layer 180 is formed on the exposed surfaces of the semiconductor device structure 100 (e.g., on the IL (if any), sidewalls of the gate spacers 138, the top surfaces of the ILD layer 164, the CESL 162, and the cap layer 139). The gate dielectric layer 180 may be formed of a material chemically different than that of the sacrificial gate dielectric layer 132. The gate dielectric layer 180 may include or made of a high-k dielectric material. The gate dielectric layer 180 may be a conformal layer formed by a conformal process, such as an ALD process, a PECVD process, a molecular-beam deposition (MBD) process, or the like, or a combination thereof.

After formation of the IL (if any) and the gate dielectric layer 180, the gate electrode layer 182 is formed on the gate dielectric layer 180. The gate electrode layer 182 filles the openings 166 (FIG. 25A) and surrounds a portion of each of the first semiconductor layers 106. The gate electrode layer 182 includes one or more layers of conductive material, such as polysilicon, aluminum, copper, titanium, tantalum, tungsten, cobalt, molybdenum, tantalum nitride, nickel silicide, cobalt silicide, TIN, WN, WCN, TiAl, TiTaN, TiAIN, TaN, TaCN, TaC, TaSiN, metal alloys, other suitable materials, and/or combinations thereof. The gate electrode layers 182 may be formed by PVD, CVD, ALD, electro-plating, or other suitable method. In some embodiments, one or more optional conformal layers (not shown) can be conformally (and sequentially, if more than one) deposited between the gate dielectric layer 180 and the gate electrode layer 182. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

Portions of the gate electrode layer 182, the one or more optional conformal layers (if any), and the gate dielectric layer 180 above the top surfaces of the ILD layer 164, the CESL 162, the cap layer 139 (if any), and the gate spacers 138 may be removed by a planarization process, such as by a CMP process. After the CMP process, the top surfaces of the isolation trench structure 2134a, the ILD layer 164, the CESL 162, the gate spacers 138, the cap layer 139, and the gate electrode layer 182 are substantially co-planar.

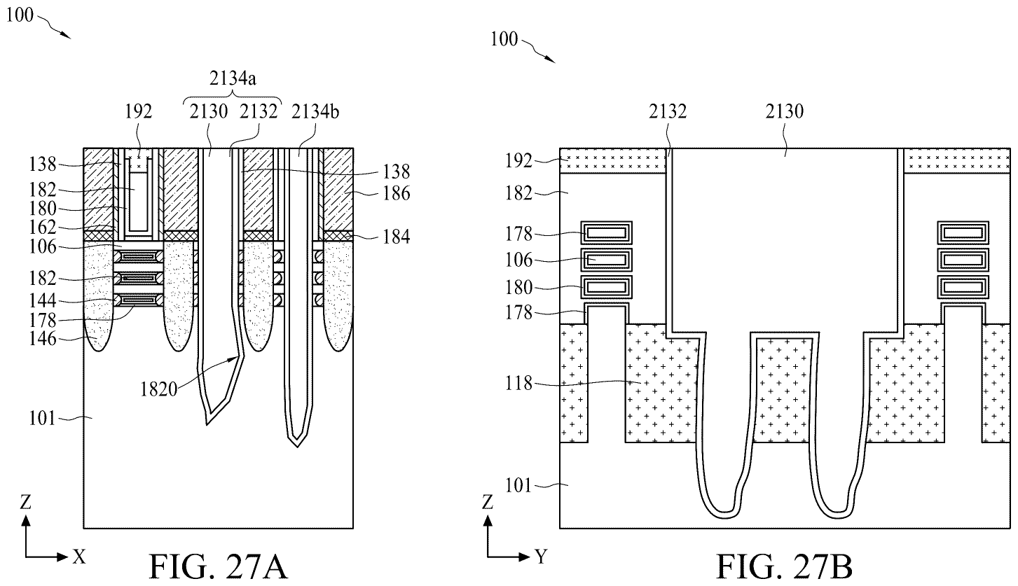

In FIGS. 27A and 27B, the gate electrode layer 182 may be subject to one or more metal gate etching back (MGEB) processes. The MGEB processes are performed so that the top surfaces of the gate electrode layer 182 and the gate dielectric layer 180 are recessed to a level below the top surface of the gate spacers 138. In some embodiments, the gate spacers 138 are also recessed to a level below the top surface of the ILD layer 164. A self-aligned contact layer 192 is formed over the gate electrode layer 182. The self-aligned contact layer 192 may be a dielectric material (e.g., SiN) having an etch selectivity relative to the ILD layer 164. After formation of the self-aligned contact layer 192, the cap layer 139 is removed and contact openings are formed through the ILD layer 164 and the CESL 162 to expose the epitaxial source/drain features 146. The self-aligned contact layer 192 protects the gate electrode layer 182 during formation of the contact openings. A silicide layer 184 is then formed on the epitaxial source/drain features 146, and a S/D contact 186 is formed in the contact opening on the silicide layer 184. The contact 186 may include an electrically conductive material, such as Ru, Mo, Co, Ni. W, Ti, Ta, Cu, Al, TiN, or TaN. While not shown, a barrier layer (e.g., TiN, TaN, or the like) may be formed on sidewalls of the contact openings prior to forming the S/D contacts 186. Then, a planarization process, such as CMP, is performed to remove excess deposition of the contact material and expose the top surface of the gate electrode layer 182.

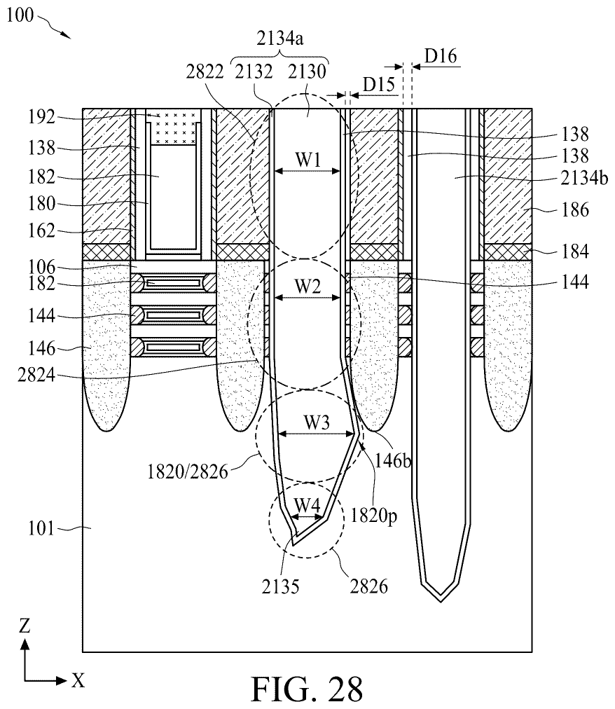

FIG. 28 illustrates a cross-sectional view of a portion of the semiconductor device structure 100 showing the isolation trench structure, in accordance with some embodiments. As can be seen, the isolation trench structure 2134a has a bottom 2135 extending into the substrate 101. The lower portion 2826 of the isolation trench structure 2134a is formed with a bowing profile 1820 extending outwardly from one side of the isolation trench structure 2134a. In some embodiments, the prominent point 1820p of the bowing profile 1820 may be at an elevation slightly below the bottom surface 146b of the immediately adjacent epitaxial source/drain feature 146. The isolation trench structure 2134a near the S/D contact 186 may have one side recessed inwardly to provide an upper portion 2822 with a first width W1. The middle portion 2824 of the isolation trench structure 2134a near the epitaxial source/drain feature 146 may have a second width W2 greater than the first width W1. The lower portion 2826 of the isolation trench structure 2134a near the bowing profile 1820 may have a dimension gradually increased from the second width W2 to a third width W3 along a depth direction of the isolation trench structure 2134a. The bottom portion of the isolation trench structure 2134a below the bowing profile 1820 may have a tapering shape with a dimension gradually decreased from the third width W3 to a fourth width W4. In some embodiments, the fourth width W4 is less than the first width W1. While not shown, in some embodiments where the fin-cut process was not performed effectively, the sacrificial gate electrode layer 134 may remain between the dielectric liner 2132 and the gate spacer 138 adjacent the upper portion of the isolation trench structure 2134a. Portions of the first semiconductor layers 106 and inner spacers 144 are disposed adjacent the middle portion of the isolation trench structure 2134a and between the dielectric liner 2132 and the epitaxial source/drain feature 146.

Due to the pattern shift and thus the shift of the trench patterns 1402a′ and 1402b′ (FIG. 14A), the dielectric liner 2132 on a first side of the isolation trench structure 2134a may have a portion in direct contact with the S/D contact 186 and the dielectric liner 2132 on a second side of the isolation trench structure 2134a may have a portion in direct contact with the gate spacer 138. Particularly, the remaining gate spacer 138 disposed against the dielectric liner 2132 on the second side of the isolation trench structure 2134a may have a first thickness D15 and the gate spacer 138 disposed away from the isolation trench structure 2134a and immediately adjacent the isolation trench structure 2134b may have a second thickness D16 that is greater than the first thickness D15.

FIG. 29 illustrates a cross-sectional view of a portion of the semiconductor device structure 100 showing the isolation trench structure, in accordance with some embodiments. The embodiment of FIG. 29 is substantially identical to the embodiment of FIG. 28 except that the gate spacer 138 remains on both sides of the isolation trench structure 2134a have unequal thickness, as discussed above with respect to FIG. 16A-1. In such cases, the dielectric liner 2132 on a first side of the isolation trench structure 2134a may have a portion in direct contact with a first portion of the gate spacer 138 and the dielectric liner 2132 on a second side of the isolation trench structure 2134a may have a portion in direct contact with a second portion of the gate spacer 138. Particularly, the first portion of the gate spacer 138 disposed against the dielectric liner 2132 on the first side of the isolation trench structure 2134a may have a third thickness D17, which is less than the first thickness D15 of the gate spacer 138 disposed against the dielectric liner 2132 on the second side of the isolation trench structure 2134a.

It is understood that the semiconductor device structure 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structure 100 may also include backside contacts (not shown) on the backside of the substrate 101 so that either source or drain of the epitaxial S/D features 146 is connected to a backside power rail (e.g., positive voltage VDD or negative voltage VSS) through the backside contacts.

Embodiments of the present disclosure provide an improved CPODE process for patterning transistors of a multi-gate device without photoresist peeling defects. The improved CPODE process enables aggressive scaling of isolation trench structures in the fin structure for prevention of current leakage through epitaxial source/drain features, transistors, and silicon substrate. In cases where long and short isolation trench structures are involved in a semi-isolated pattern region (e.g., regions where two CPODE patterns are arranged adjacent to an isolated pattern region having no CPODE pattern), the patterned opening in the photoresist for the long or short isolation trench is shifted away with respect to the center of the underlying gate structure. The shifting ensures the critical dimension of the patterned opening to be equal to or less than the pitch size of the patterned openings. As a result, the peeling of the photoresist mandrels is avoided. In addition, the shifting of a portion of the patterned opening allows the subsequent isolation trench structures to be formed without undercutting the epitaxial source/drain features.

A semiconductor device structure, along with methods of forming such, are described. An embodiment is a semiconductor device structure. The semiconductor device structure includes a substrate, a source/drain feature disposed over the substrate, a gate spacer disposed over the source/drain feature, and a first isolation trench structure disposed over the substrate. The first isolation trench includes an upper portion adjacent to the gate spacer, a middle portion disposed below the upper portion and adjacent to a first side of the source/drain feature, and a lower portion disposed below the middle portion and extending into the substrate, wherein the lower portion has a bowing profile extending outwardly from one side of the first isolation trench structure.

Another embodiment is a semiconductor device structure. The semiconductor device structure includes a substrate, a first fin structure extending from the substrate along a first direction, a first gate structure disposed across the first fin structure and extending along a second direction perpendicular to the first direction, and a first isolation trench structure disposed in the first gate structure and extending through a portion of the first fin structure and into the substrate. The first isolation trench structure includes a first section, a second section, and a third section connecting the first and second sections, wherein the third section is laterally offset from the first section by a distance.

A further embodiment is a method. The method includes forming a plurality of fin structures from a substrate along a first direction, each fin structure having a plurality of semiconductor layers vertically stacked. The method also includes forming a plurality of gate structures across the plurality of fin structures along a second direction, depositing a mask layer over the plurality of gate structures, depositing a photoresist layer over the mask layer, forming a pattern in the photoresist layer, wherein the pattern comprises a first opening that is shifted in a first direction away from a center of a first gate structure of the plurality of gate structures, and a second opening in alignment with a center of a second gate structure of the plurality of gate structures. The method also includes patterning the mask layer to transfer the pattern from the photoresist layer to the mask layer, removing portions of a first fin structure and a second fin structure of the plurality of fin structures using the patterned mask layer to form first and second isolation trenches, respectively, and filling the first and second isolation trenches with a dielectric material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a substrate;
a source/drain feature disposed over the substrate;
a gate spacer disposed over the source/drain feature; and
a first isolation trench structure disposed over the substrate, the first isolation trench comprising:
an upper portion adjacent to the gate spacer;
a middle portion disposed below the upper portion and adjacent to a first side of the source/drain feature; and
a lower portion disposed below the middle portion and extending into the substrate, wherein the lower portion has a bowing profile extending outwardly from one side of the first isolation trench structure.

2. The semiconductor device structure of claim 1, further comprising:
a sacrificial gate electrode layer disposed between the gate spacer and the upper portion of the first isolation trench structure.

3. The semiconductor device structure of claim 1, wherein the upper portion of the first isolation trench structure has a first width, the middle portion of the first isolation trench structure has a second width greater than the first width, the lower portion of the first isolation trench structure has a third width greater than the second width.

4. The semiconductor device structure of claim 3, wherein the first isolation trench structure further comprises a bottom portion disposed below the lower portion and has a fourth width less than the first width.

5. The semiconductor device structure of claim 1, further comprising:
a second isolation trench structure disposed adjacent to a second side of the source/drain feature, wherein the second isolation trench structure has a bottom at an elevation lower than a bottom of the first isolation trench structure.

6. The semiconductor device structure of claim 5, wherein the first isolation trench structure has a section laterally offset from the second isolation trench in a longitudinal direction of the first isolation trench structure.

7. The semiconductor device structure of claim 5, wherein the first isolation trench structure has asymmetric profile in a depth direction of the first isolation trench structure, and the second isolation trench structure has a symmetric profile in a depth direction of the second isolation trench structure.

8. A semiconductor device structure, comprising:
a substrate;
a first fin structure extending from the substrate along a first direction;
a first gate structure disposed across the first fin structure and extending along a second direction perpendicular to the first direction; and
a first isolation trench structure disposed in the first gate structure and extending through a portion of the first fin structure and into the substrate, the first isolation trench structure comprising:
a first section;
a second section; and
a third section connecting the first and second sections, wherein the third section is laterally offset from the first section by a distance.

9. The semiconductor device structure of claim 8, wherein a lower portion of the first isolation trench structure has a bowing profile.

10. The semiconductor device structure of claim 9, wherein the bowing profile is extended outwardly from one side of the first isolation trench structure.

11. The semiconductor device structure of 8, wherein the third section of the first isolation trench structure has an asymmetric profile with respect to an imaginary line passing through a center of the first isolation trench structure in a depth direction of the first isolation trench structure.

12. The semiconductor device structure of claim 8, further comprising:
a second fin structure extending from the substrate along the first direction; and
a second gate structure disposed across the second fin structure and extending along he second direction; and
a second isolation trench structure disposed in the second gate structure and extending through a portion of the second fin structure and into the substrate.

13. The semiconductor device structure of 12, wherein the second isolation trench structure has a symmetric profile with respect to an imaginary line passing through a center of the second isolation trench structure in a depth direction of the second isolation trench structure.

14. The semiconductor device structure of claim 12, wherein the third section of the first isolation trench structure has a first length and the second isolation trench structure has a second length that is substantially equal to the first length.

15. The semiconductor device structure of claim 14, wherein the first, second, and third sections of the first isolation trench structure have a combined length that is greater than the second length of the second isolation trench structure.

16. The semiconductor device structure of claim 12, wherein the third section of the first isolation trench structure has a first depth, and the second isolation trench structure has a second depth greater than the first depth.

17. The semiconductor device structure of claim 16, wherein the first section of the first isolation trench structure has a third depth greater than the first depth of the third section of the first isolation trench structure.

18. A method for forming a semiconductor device structure, comprising:
forming a plurality of fin structures from a substrate along a first direction, each fin structure having a plurality of semiconductor layers vertically stacked;
forming a plurality of gate structures across the plurality of fin structures along a second direction;
depositing a mask layer over the plurality of gate structures;
depositing a photoresist layer over the mask layer;
forming a pattern in the photoresist layer, wherein the pattern comprises:
a first opening that is shifted in a first direction away from a center of a first gate structure of the plurality of gate structures; and
a second opening in alignment with a center of a second gate structure of the plurality of gate structures;
patterning the mask layer to transfer the pattern from the photoresist layer to the mask layer;
removing portions of a first fin structure and a second fin structure of the plurality of fin structures using the patterned mask layer to form first and second isolation trenches, respectively; and
filling the first and second isolation trenches with a dielectric material.

19. The method of claim 18, wherein removing portions of a first fin structure and a second fin structure is performed using a self-aligned etch process with a high selectivity towards the semiconductor layers.

20. The method of claim 18, wherein the first isolation trench has a bowing profile extending in a second direction opposite to the first direction.
